(19) United States
(12) Patent Application Publication
(10) Pub. No.: US 2016/0155984 A1
(43) Pub. Date: Jun. 2, 2016

(54) Display Module and Method for Manufacturing Display Module

(71) Applicant: Semiconductor Energy Laboratory Co., Ltd., Kanagawa-ken (JP)

(72) Inventors: Shunpei Yamazaki, Tokyo (JP); Yoshiharu HIRAKATA, Ebina (JP); Yasuhiro JINBO, lsehara (JP)

(73) Assignee: Semiconductor Energy Laboratory Co., Ltd., Kanagawa-ken (JP)

(21) Appl. No.: 14/950,250

(22) Filed: Nov. 24, 2015

(30) Foreign Application Priority Data
Nov. 28, 2014 (JP) 2014-241556
Dec. 1, 2014 (JP) 2014-242992
Mar. 9, 2015 (JP) 2015-045490
Jun. 29, 2015 (JP) 2015-129863

(51) Int. Cl. H01L 51/52; H01L 51/56; H01L 27/32

(52) U.S. Cl. CPC H01L 51/5246; H01L 27/323; H01L 27/3244; H01L 51/56; H01L 2251/5338

(57) ABSTRACT

To provide a novel, highly convenient or reliable display module or a novel, highly convenient or reliable method for manufacturing a display module, a display module including the following has been devised: a first base which is flexible and supports a terminal, a second base which is flexible and overlaps with the first base, a bonding layer which bonds the first base and the second base, a flexible printed circuit electrically connected to the terminal, a display element electrically connected to the terminal, and an insulating layer in contact with the first base, the second base, the bonding layer, and the flexible printed circuit. The display element is provided with a layer containing a light-emitting organic compound.

### TECHNICAL FIELD

One embodiment of the present invention relates to a display module, a semiconductor device, or a method for manufacturing the display module.

Note that one embodiment of the present invention is not limited to the above technical field. The technical field of one embodiment of the invention disclosed in this specification and the like relates to an object, a method, or a manufacturing method. In addition, one embodiment of the present invention relates to a process, a machine, manufacture, or a composition of matter. Specifically, examples of the technical field of one embodiment of the present invention disclosed in this specification include a semiconductor device, a display device, a light-emitting device, a power storage device, a memory device, a method of driving any of them, and a method of manufacturing any of them.

### BACKGROUND ART

Functions of some functional elements are impaired because of impurity diffusion. In order to maintain the functions of such functional elements, the following invention is known (Patent Document 1): a functional element is sealed in a space surrounded by a substrate provided with the functional elements, a sealing substrate, and a sealant for bonding the substrate and the sealing substrate.

Another invention (Patent Document 2) is known, as follows: in a manufacturing process of a light-emitting device, a light-emitting panel is manufactured which is at least partly curved by processing the shape to be molded after the manufacture of an electrode layer and/or an element layer, and a protective film covering a surface of the light-emitting panel which is at least partly curved is formed, so that a light-emitting device using the light-emitting panel has a more useful function and higher reliability.

### REFERENCE

### Patent Document

[Patent Document 1] United States Published Patent Application No. 2007/0170854
[Patent Document 2] Japanese Published Patent Application No. 2011-003537

### DISCLOSURE OF INVENTION

An object of one embodiment of the present invention is to provide a novel, highly convenient or reliable display module. Another object of one embodiment of the present invention is to provide a novel, highly convenient or reliable method for manufacturing a display module. Another object of one embodiment of the present invention is to provide a novel display module, a novel method for manufacturing a display module, or a novel semiconductor device.

Note that the descriptions of these objects do not disturb the existence of other objects. In one embodiment of the present invention, there is no need to achieve all the objects. Other objects will be apparent from and can be derived from the description of the specification, the drawings, the claims, and the like.

(1) One embodiment is a display module including a terminal, a first base, a second base, a bonding layer, a display element, a flexible printed circuit, and an insulating layer.

The first base is flexible and has a function of supporting the terminal.

The second base is flexible and has a region overlapping with the first base.

The bonding layer has a function of bonding the first base and the second base.

The display element is provided between the first base and the second base and is electrically connected to the terminal.

The flexible printed circuit is electrically connected to the terminal.

The insulating layer is in contact with the first base, the second base, the bonding layer, and the flexible printed circuit.

The display module of the above embodiment of the present invention includes the first base which is flexible and supports the terminal, a second base which is flexible and overlaps with the first base, the bonding layer which bonds the first base and the second base, the flexible printed circuit electrically connected to the terminal, the display element electrically connected to the terminal, and the insulating layer in contact with the first base, the second base, the bonding layer, and the flexible printed circuit. Accordingly, it is possible to suppress impurity diffusion to a region surrounded by the first base, the second base, and the insulating layer, for example, a layer containing a light-emitting organic compound. Thus, a novel, highly convenient or reliable display module can be provided.

(2) The one embodiment is the display module further including a resin layer, in which the insulating layer includes a region interposed between the bonding layer and the resin layer.

The display module of the above embodiment includes the insulating layer which is interposed between the bonding layer and the resin layer. Accordingly, various kinds of stresses are dispersed and therefore breakage of the insulating layer due to stress concentration can be prevented. Thus, a novel, highly convenient or reliable display module can be provided.

(3) The one embodiment is the display module in which the display element is provided with a layer containing a light-emitting organic compound.

Accordingly, it is possible to suppress diffusion of various impurities to a layer containing a light-emitting organic compound. Thus, a novel, highly convenient or reliable display module can be provided.

(4) The one embodiment is the display module further including a driver circuit. A distance between the driver circuit and an end portion of the first base or an end portion of the second base which is the closest to the driver circuit is longer than 0 mm and shorter than or equal to 1.0 mm.

(5) The one embodiment is the display module further including a driver circuit. The driver circuit is provided between the display element and the end portion of the first base. A distance between the display element and the end portion of the first base or the end portion of the second base which is the closest to the display element is longer than 0 mm and shorter than or equal to 4.0 mm.

(6) The one embodiment is the display module in which a distance between the display element and the end portion of the first base or the end portion of the second base which is the closest to the display element is longer than 0 mm and shorter than or equal to 3.0 mm.

Accordingly, the width of a frame which is formed outside a region in which the display elements are arranged can be reduced. Thus, a novel, highly convenient or reliable display module can be provided.

(7) Another embodiment is a display module including a first terminal portion, a second terminal portion, a first base, a second base, a bonding layer, a display element, a touch sensor, a first flexible printed circuit, a second flexible printed circuit, and an insulating layer.

The first base has a function of supporting the first terminal portion.

The second base has a function of supporting a region overlapping with the first base and the second terminal portion.

The bonding layer has a function of bonding the first base and the second base.

The display element is provided between the first base and the second base and is electrically connected to the first terminal portion.

The touch sensor is provided between the first base and the second base and is electrically connected to the second terminal portion.

The first flexible printed circuit is electrically connected to the first terminal portion.

The second flexible printed circuit is electrically connected to the second terminal portion.

The insulating layer is in contact with the first base, the second base, the bonding layer, the first flexible printed circuit, and the second flexible printed circuit.

The display module of the above embodiment includes the display elements arranged in a region surrounded by the first base which is flexible, the second base which is flexible, and the insulating layer. Accordingly, it is possible to suppress diffusion of various impurities to a region surrounded by the first base, the second base, and the insulating layer. Thus, a novel, highly convenient or reliable display module can be provided.

(8) Another embodiment is a method for manufacturing the above display module including a first step, a second step, and a third step.

In the first step, a terminal, a process member including a first base which supports the terminal, a second base which has a region overlapping with the first base, a bonding layer which bonds the first base and the second base, a display element which is provided between the first base and the second base and is electrically connected to the terminal, and a flexible printed circuit electrically connected to the terminal is prepared, and a mask is formed in a region overlapping with a terminal portion of the flexible printed circuit.

In the second step, an insulating layer in contact with the first base, the second base, the bonding layer, and the flexible printed circuit is formed by an atomic layer deposition (ALD) method.

In the third step, part of the insulating layer is removed together with the mask and an opening is formed in a region of the insulating layer which overlaps with the terminal portion of the flexible printed circuit.

The method for manufacturing a display module of the above embodiment includes a first step of forming a mask in a region overlapping with the terminal portion of the flexible printed circuit, a second step of forming the insulating layer by an atomic layer deposition method, and a third step of forming the opening in the region of the insulating layer which overlaps with the terminal portion of the flexible printed circuit. Accordingly, the insulating layer having the opening in the terminal portion of the flexible printed circuit can be formed. Thus, a novel, highly convenient or reliable method for manufacturing a display module can be provided.

One embodiment of the present invention can provide a novel, highly convenient or reliable display module. Another embodiment of the present invention can provide a novel, highly convenient or reliable method for manufacturing a display module. Another embodiment of the present invention can provide a novel display module, a novel method for manufacturing a display module, or a novel semiconductor device.

Note that the description of these effects does not disturb the existence of other effects. One embodiment of the present invention does not necessarily achieve all the effects listed above. Other effects will be apparent from and can be derived from the description of the specification, the drawings, the claims, and the like.

### BRIEF DESCRIPTION OF DRAWINGS

FIGS. 1A to 1C illustrate structures of display modules of one embodiment.

FIGS. 2A to 2C illustrate structures of display modules of one embodiment.

FIGS. 3A to 3C illustrate structures of display panels of one embodiment.

FIGS. 4A to 4C illustrate structures of display panels of one embodiment.

FIGS. 5A to 5D illustrate a structure of a display module of one embodiment.

FIG. 6 illustrates the structure of the display module of one embodiment.

FIG. 7 illustrates a method for manufacturing a display module of one embodiment.

FIGS. 8A to 8C illustrate the method for manufacturing a display module of one embodiment.

FIG. 9 illustrates a structure of a deposition apparatus of one embodiment.

FIGS. 10A1, 10A2, 10A3, 10B, and 10C illustrate a structure of a support portion of one embodiment.

FIGS. 11A to 11C illustrate a structure of a support portion of one embodiment.

FIGS. 12A, 12B, 12C1, and 12C2 illustrate a structure of a data processing device of one embodiment.

FIGS. 13A1, 13A2, 13B1, 13B2, 13C, 13D1, 13D2, 13E1, and 13E2 are schematic views illustrating a manufacturing process of a stack of one embodiment.

FIGS. 14A1, 14A2, 14B1, 14B2, 14C, 14D1, 14D2, 14E1, and 14E2 are schematic views illustrating a manufacturing process of a stack of one embodiment.

FIGS. 15A1, 15A2, 15B, 15C, 15D1, 15D2, 15E1, and 15E2 are schematic views illustrating a manufacturing process of a stack of one embodiment.

FIGS. 16A1, 16A2, 16B1, 16B2, 16C1, 16C2, 16D1, and 16D2 are schematic views illustrating manufacturing processes of stacks, each having an opening in a support, of one embodiment.

FIGS. 17A1, 17A2, 17B1, and 17B2 are schematic views illustrating structures of process members of one embodiment.

FIG. 18A illustrates a structure of a fabricated display module of an example, and FIG. 18B shows photographs of the display module.

FIGS. 19A, 19B, 19C1, and 19C2 illustrate a method for forming an insulating layer of a display module of an example.

FIGS. 20A and 20B show photographs of the external appearance and display quality of the display module of the example.

FIGS. 21A to 21C are external views of a bend tester and a pencil hardness tester.

FIG. 22 shows a transmittance of a material which can be used for an insulating layer of the example.

FIG. 23 illustrates a structure of a display module of one embodiment.

FIGS. 24A1, 24A2, 24A3, 24B1, 24B2, 24C1, and 24C2 illustrate a structure of a data processing device of one embodiment.

### BEST MODE FOR CARRYING OUT THE INVENTION

A display module of one embodiment of the present invention includes a first base which supports a terminal, a second base which overlaps with the first base, a bonding layer which bonds the first base and the second base, a flexible printed circuit electrically connected to the terminal, a display element electrically connected to the terminal, and an insulating layer in contact with the first base, the second base, the bonding layer, and the flexible printed circuit.

Accordingly, it is possible to suppress impurity diffusion to a region surrounded by the insulating layer. Thus, a novel, highly convenient or reliable display module can be provided.

Embodiments and examples will be described in detail with reference to drawings. Note that the present invention is not limited to the description below, and it is easily understood by those skilled in the art that various changes and modifications can be made without departing from the spirit and scope of the present invention. Accordingly, the present invention should not be interpreted as being limited to the content of the embodiments and examples below. Note that in the structures of the invention described below, the same portions or portions having similar functions are denoted by the same reference numerals in different drawings, and description of such portions is not repeated.

### Embodiment 1

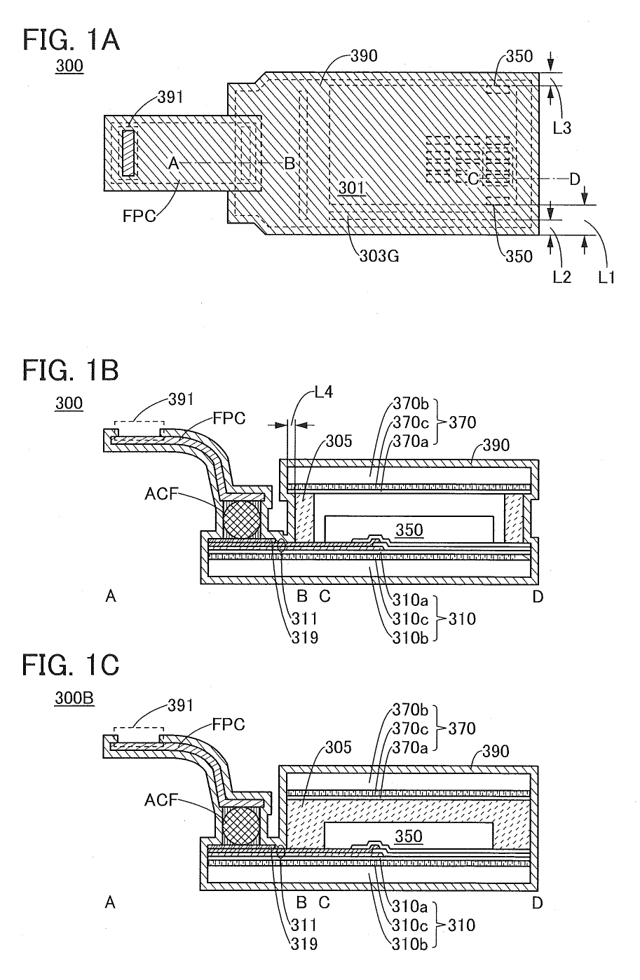

In this embodiment, a structure of a display module of one embodiment of the present invention will be described with reference to FIGS. 1A to 1C.

FIGS. 1A to 1C illustrate the structure of the display module of one embodiment of the present invention. FIG. 1A is a top view of a display module 300 of one embodiment of the present invention, and FIG. 1B is a cross-sectional view taken along the lines A-B and C-D in FIG. 1A.

FIG. 1C is a cross-sectional view illustrating a structure of a display module 300B which has a structure different from the display module 300 illustrated in FIG. 1B.

### <Structure Example 1 of Display Module>

The display module 300 described in this embodiment includes a terminal 319, a first base 310 which supports the terminal 319, a second base 370 which has a region overlapping with the first base 310, a bonding layer 305 which has a function of bonding the first base 310 and the second base 370, a display element 350 which is provided between the first base 310 and the second base 370 and is electrically connected to the terminal 319, a flexible printed circuit FPC electrically connected to the terminal 319, and an insulating layer 390 in contact with the first base 310, the second base 370, the bonding layer 305, and the flexible printed circuit FPC (see FIG. 1B).

Accordingly, it is possible to suppress impurity diffusion to a region surrounded by the first base, the second base, and the insulating layer, for example, a display element or the like. Specifically, it is possible to suppress impurity diffusion to a layer containing a liquid crystal material, a layer containing a light-emitting organic compound, or the like. Thus, a novel, highly convenient or reliable display module can be provided.

The display module 300 includes a wiring 311 electrically connected to the terminal 319 and the display element 350.

The display module 300 further includes a driver circuit 303G between a region 301 in which the display element 350 is provided and the end portion of the first base 310 (see FIG. 1A).

In the display module 300 described with reference to FIG. 1B, a region surrounded by the first base 310, the second base 370, and the bonding layer 305 includes a material different from a material used for the bonding layer 305 (e.g., gas, liquid, or liquid crystal).

In contrast, the display module 300B described with reference to FIG. 1C is different from the display module 300 described with reference to FIG. 1B in that a region between the display element 350 and the second base 370 is filled with the bonding layer 305.

The display module 300 includes the driver circuit 303G, and a distance L2 between the driver circuit 303G and the end portion of the first base 310 which is the closest to the driver circuit 303G is longer than 0 mm and shorter than or equal to 1.0 mm, preferably shorter than or equal to 0.3 mm.

For example, in the display module 300, the driver circuit 303G is provided between the end portion of the first base 310 and the display element 350, and a distance L1 between the display element 350 and the end portion of the first base 310 or the end portion of the second base 370 which is the closest to the display element 350 is longer than 0 mm and shorter than or equal to 4.0 mm, preferably shorter than or equal to 2 mm and further preferably shorter than or equal to 1.0 mm.

For example, the display module 300 includes the display element 350, and a distance L3 between the display element 350 and the end portion of the first base 310 or the end portion of the second base 370 which is the closest to the display element 350 is longer than 0 mm and shorter than 3.0 mm, preferably shorter than 1.5 mm. Accordingly, a display module having a narrow frame can be provided.

For example, the display module 300 includes the bonding layer 305. A distance L4 corresponding to the longest distance among a distance between the end portion of the first base 310 overlapping with the second base 370 and an end portion of the bonding layer 305 and a distance between the end portion of the second base 370 overlapping with the first base 310 and the end portion of the bonding layer 305 is longer than or equal to 0.3 mm, preferably longer than or equal to 0.5 mm and shorter than 10 mm. For example, the insulating layer 390 can be formed by an atomic layer deposition (ALD) method by depositing a deposition material to a substantially uniform thickness without depending on the direction of the surface of a process member (see FIG. 1B).

Individual components included in the display module 300 will be described below. Note that these components cannot be clearly distinguished from each other and one component also serves as another component or includes part of another component in some cases.

### <<Display Module 300>>

The display module 300 includes the terminal 319, the first base 310, the second base 370, the bonding layer 305, the display element 350, the flexible printed circuit FPC, or the insulating layer 390.

The display module 300 includes the wiring 311.

### <<First Base 311>>

At least one of the first base 310 and the second base 370 includes a light-transmitting region in a region overlapping with the display element 350.

There is no particular limitation on the material for the first base 310 as long as it has heat resistance high enough to withstand a manufacturing process and a thickness and a size that allow the first base 310 to be placed in a manufacturing apparatus.

For the first base 310, an organic material, an inorganic material, a composite material of an organic material and an inorganic material, or the like can be used. For example, an inorganic material such as glass, ceramic, or metal can be used for the first base 310.

Specifically, non-alkali glass, soda-lime glass, potash glass, crystal glass, or the like can be used for the first base 310. Specifically, an inorganic oxide film, an inorganic nitride film, an inorganic oxynitride film, or the like can be used for the first base 310. For example, a silicon oxide film, a silicon nitride film, a silicon oxynitride film, or an alumina film can be used for the first base 310. SUS, aluminum, or the like can be used for the first base 310.

For example, an organic material such as a resin, a resin film, or plastic can be used for the first base 310. Specifically, a resin film or a resin plate of polyester, polyolefin, polyamide, polyimide, polycarbonate, an acrylic resin, or the like can be used for the first base 310.

For example, a composite material such as a resin film to which a metal plate, a thin glass plate, or a film of an inorganic material or the like is attached can be used for the first base 310. For example, a composite material formed by dispersing a fibrous or particulate metal, glass, inorganic material, or the like into a resin film can be used for the first base 310. For example, a composite material formed by dispersing a fibrous or particulate resin, an organic material, or the like into an inorganic material can be used for the first base 310.

Furthermore, a single-layer material or a material in which a plurality of layers are stacked can be used for the first base 310. For example, a material in which a base, an insulating film which prevents diffusion of impurities contained in the base, and the like are stacked can be used for the first base 310. Specifically, a material in which glass and one or a plurality of films which prevent diffusion of impurities contained in the glass and which are selected from a silicon oxide film, a silicon nitride film, a silicon oxynitride film, and the like are stacked can be used for the first base 310. Alternatively, a material in which a resin, a film which prevents diffusion of impurities contained in the resin, such as a silicon oxide film, a silicon nitride film, or a silicon oxynitride film, and the like are stacked can be used for the first base 310.

For the first base 310, a flexible material can be used. For example, it is possible to use a material having flexibility high enough to be bent or be folded. Specifically, it is possible to use a material which can be bent at a radius of curvature of 5 mm or more, preferably 4 mm or more, further preferably 3 mm or more, and particularly preferably 1 mm or more. For the first base 310, it is possible to use a material with a thickness greater than or equal to 2.5 μm and less than or equal to 3 μm, preferably greater than or equal to 5 μm and less than or equal to 1.5 μm and further preferably greater than or equal to 10 μm and less than or equal to 500 μm.

For example, a stack including a flexible base 310b, a barrier film 310a which prevents impurity diffusion, and a resin layer 310c which bonds the base 310b and the barrier film 310a can be used for the first base 310.

Specifically, a film containing a stacked-layer material of a 600-nm-thick silicon oxynitride film and a 200-nm-thick silicon nitride film can be used as the barrier film 310a.

Alternatively, a film including a stacked-layer material of a 600-nm-thick silicon oxynitride film, a 200-nm-thick silicon nitride film, a 200-nm-thick silicon oxynitride film, a 140-nm-thick silicon nitride oxide film, and a 100-mm-thick silicon oxynitride film stacked in this order can be used as the barrier film 310a.

Specifically, a resin film, a resin plate, a stack, or the like of polyester, polyolefin, polyamide, polyimide, polycarbonate, an acrylic resin, or the like can be used for the base 310b.

Specifically, a material including polyester, polyolefin, polyamide (e.g., nylon or aramid), polyimide, polycarbonate, an acrylic resin, a urethane resin, an epoxy resin, a resin having a siloxane bond, such as a silicone resin, or the like can be used for the resin layer 310c.

### <<Second Base 370>>

The material which can be used for the first base 310 can be used for the second base 370.

For example, a stack including a flexible base 370b, a barrier film 370a which prevents impurity diffusion, and a resin layer 370c which bonds the base 370b and the barrier film 370a can be used for the second base 370.

### <<Bonding Layer 305>>

For the bonding layer 305, it is possible to use a material which has a function of bonding the first base 310 and the second base 370.

For the bonding layer 305, an inorganic material, an organic material, a composite material of an inorganic material and an organic material, or the like can be used.

For example, glass with a melting point of 400° C. or lower, preferably 300° C. or lower, can be used for the bonding layer 305.

For example, an organic material such as a resin having thermal fusibility or a curable resin can be used for the bonding layer 305.

For example, an organic material such as a light curable adhesive, a reactive curable adhesive, a thermosetting adhesive, and/or an anaerobic adhesive can be used for the bonding layer 305.

Specifically, an adhesive containing an epoxy resin, an acrylic resin, a silicone resin, a phenol resin, a polyimide resin, an imide resin, a polyvinyl chloride (PVC) resin, a polyvinyl butyral (PVB) resin, and an ethylene vinyl acetate (EVA) resin, or the like can be used.

### <<Wiring 311 or Terminal 319>>

A conductive material can be used for the wiring 311 or the terminal 319.

For example, an inorganic conductive material, an organic conductive material, a metal material, a conductive ceramic material, or the like can be used for the wiring 311 or the terminal 319.

Specifically, a metal element selected from aluminum, gold, platinum, silver, copper, chromium, tantalum, titanium, molybdenum, tungsten, nickel, iron, cobalt, palladium, and manganese, or the like can be used for the wiring 311 or the terminal 319. Alternatively, an alloy including any of the above-described metal elements, or the like can be used for the wiring 311 or the terminal 319. Further alternatively, an alloy including any of the above-described metal elements in combination, or the like can be used for the wiring 311 or the terminal 319. In particular, an alloy of copper and manganese is suitably used in microfabrication with the use of a wet etching method.

Specifically, a two-layer structure in which a titanium film is stacked over an aluminum film, a two-layer structure in which a titanium film is stacked over a titanium nitride film, a two-layer structure in which a tungsten film is stacked over a titanium nitride film, a two-layer structure in which a tungsten film is stacked over a tantalum nitride film or a tungsten nitride film, a three-layer structure in which a titanium film, an aluminum film, and a titanium film are stacked in this order, or the like can be used.

Specifically, a conductive oxide such as indium oxide, indium tin oxide, indium zinc oxide, zinc oxide, or zinc oxide to which gallium is added can be used for the wiring 311 or the terminal 319.

Specifically, a film including graphene or graphite can be used for the wiring 311 or the terminal 319.

For example, a film including graphene oxide is formed and is reduced, so that a film including graphene can be formed. As a reducing method, a method using heat, a method using a reducing agent, or the like can be employed.

Specifically, a conductive high molecule can be used for the wiring 311 or the terminal 319.

### <<Display Element 350>>

A variety of display elements can be used for the display element 350.

For example, display media whose contrast, luminance, reflectance, transmittance, or the like is changed by an electrical or magnetic effect can be used as a display element.

Specifically, an electroluminescence (EL) element (e.g., an EL element including organic and inorganic materials, an organic EL element, or an inorganic EL element), an LED (e.g., a white LED, a red LED, a green LED, or a blue LED), a transistor (a transistor which emits light depending on current), an electron emitter, a liquid crystal element, electronic ink, an electrophoretic element, a grating light valve (GLV), a plasma display panel (PDP), a display element using micro electro mechanical systems (MEMS), a digital micromirror device (DMD), a digital micro shutter (DMS), MIRASOL (registered trademark), an interferometric modulator (IMOD) element, a MEMS shutter display element, an optical-interference-type MEMS display element, an electrowetting element, or the like can be used.

### <<Flexible Printed Circuit FPC>>

The flexible printed circuit FPC includes a wiring electrically connected to the terminal 319, a base which supports the wiring, and a coating layer which has a region overlapping with the wiring. The wiring includes a region between the base and the coating layer and a region not overlapping with the coating layer.

Note that the region of the wiring which does not overlap with the coating layer can be used for a terminal of the flexible printed circuit FPC.

A conductive material can be used for the wiring of the flexible printed circuit FPC. For example, the materials which can be used for the wiring 311 and the like can be used for the wiring of the flexible printed circuit FPC. Specifically, copper or the like can be used.

A material with which an insulating region is formed in a region in contact with the wiring of the flexible printed circuit FPC can be used for a base of the flexible printed circuit FPC.

For example, an organic material such as a resin, a resin film, or plastic can be used for the base. Specifically, a resin layer, a resin film, or a resin plate of polyester, polyolefin, polyamide, polyimide, polycarbonate, an acrylic resin, or the like can be used for the base. For example, a resin film having a glass transition temperature of higher than or equal to 150° C., preferably higher than or equal to 200° C. and further preferably higher than or equal to 250° C., can be used for the base.

Note that an anisotropic conductive film ACF can be used as a material which electrically connects the terminal of the flexible printed circuit FPC and the terminal 319. For example, a material including a conductive particle, a thermosetting resin, or the like can be used for the anisotropic conductive film ACF. Accordingly, the terminal of the flexible printed circuit FPC and the terminal 319 can be electrically connected to each other by the conductive particle or the like.

### <<Insulating Layer 390>>

The insulating layer 390 has an opening 391 in a region overlapping with the terminal of the flexible printed circuit FPC.

For example, a material including an oxide, a nitride, a fluoride, a ternary compound, a polymer, or the like can be used for the insulating layer 390. A material having higher hardness than that of the surface of the base 370 can be used for the insulating layer 390. Thus, the display module 300 which is less likely to be damaged can be provided.

Specifically, a material including aluminum oxide, hafnium oxide, aluminum silicate, hafnium silicate, lanthanum oxide, silicon oxide, strontium titanate, tantalum oxide, titanium oxide, zinc oxide, niobium oxide, zirconium oxide, tin oxide, yttrium oxide, cerium oxide, scandium oxide, erbium oxide, vanadium oxide, indium oxide, or the like can be used.

For example, a material including aluminum nitride, hafnium nitride, silicon nitride, or the like can be used.

Note that the display module may include, instead of the opening 391, a mask which can form the opening 391 between the insulating layer 390 and the terminal of the flexible printed circuit FPC. Specifically, a masking tape or the like can be used for the mask. Thus, the terminal of the flexible printed circuit FPC can be exposed by removing the mask when the display module is in use, for example.

A material having an electrically insulating property or a material which has a function of suppressing impurity diffusion can be used for the insulating layer 390.

For example, a material which suppresses permeation of water vapor can be used for the insulating layer 390. Specifically, a material with a vapor permeability of lower than or equal to 10⁻⁵ g/(m²·day), preferably lower than or equal to 10⁻⁶ g/(m²·day), or the like can be used for the insulating layer 390.

For example, a material which can be formed by an atomic layer deposition method can be used for the insulating layer 390.

Meanwhile, defects such as cracks and pinholes included in the insulating layer 390 or unevenness in thickness of the insulating layer 390 might promote impurity diffusion. When an atomic layer deposition method is employed as a method of forming the insulating layer 390, defects included in the insulating layer 390 or unevenness in thickness of the insulating layer 390 can be reduced. Moreover, the insulating layer 390 can be formed dense. Thus, the insulating layer 390 which can suppress impurity diffusion can be provided.

An atomic layer deposition method can be employed as a method of forming the insulating layer 390. By an atomic layer deposition method, damage to a process member can be reduced compared to a plasma CVD method or a thermal CVD method, for example.

Meanwhile, when the first base 310 or the second base 370 is divided from a base, a minute crack (also referred to as microcrack) might be generated on an end face of the base. Specifically, the base is scribed, and a minute crack might be generated on the end face of glass which is divided by applying pressure so that the pressure is concentrated at the scribed portion. When the insulating layer 390 is formed by an atomic layer deposition method, it is expected that a minute crack which is generated on the end face can be filled.

Note that a film including an inorganic compound whose thickness is greater than or equal to 3 nm and less than or equal to 200 nm, preferably greater than or equal to 5 nm and less than or equal to 50 nm, can be used for the insulating layer 390.

By an atomic layer deposition method which includes a step of supplying an element including a precursor and a step of supplying an element including a radical, a film including an inorganic compound which is formed by depositing a deposition material to a substantially uniform thickness without depending on the direction of the surface of a process member such that a film is formed in a region shaded by an inversely tapered shape or another structure can be used for the insulating layer 390. Thus, for example, the air containing impurities such as moisture can be prevented from being in contact with the bonding layer 305.

Note that the atomic layer deposition method includes a first step of supplying a first element to a surface of a process member and a second step of supplying a second element which reacts with the first element, in which a reaction product of the first element and the second element is deposited on the surface of the process member.

Note that in the first step, the amount of the first element which is adsorbed on the surface of the process member is limited on the basis of the process condition such as temperature. This condition is referred to as a condition under which a self-stopping mechanism operates. Accordingly, the reaction product of the first element with a limited amount and the second element can be deposited in a cycle including the first step and the second step each carried out once.

For example, by alternate repetition of the first step and the second step, the reaction product of the first element and the second element in a predetermined amount can be deposited on the surface of the process member.

After the first step, a step of exhausting the first element which is oversupplied in the first step may be carried out.

After the second step, a step of exhausting the second element which is oversupplied in the second step may be carried out.

Specifically, the process member is disposed in the first step, and the first element is supplied to a reaction chamber which is prepared in a predetermined environment. Accordingly, the first element is adsorbed on the surface of the process member.

Next, the first element which remains in the reaction chamber is exhausted while a purge gas is supplied.

In the second step, the second element is supplied. Accordingly, the first element adsorbed on the surface of the process member reacts with the second element and thus a reaction product is deposited on the surface of the process member.

Next, the second element which remains in the reaction chamber is exhausted while a purge gas is supplied.

In the following steps, the first step and the second step are alternately repeated and thus a reaction product in a predetermined amount is deposited on the surface of the process member.

A precursor or the like which is selected in accordance with the kind of a reaction product to be deposited can be used for the first element. Specifically, a volatile organometallic compound, metal alkoxide, or the like can be used for the first element.

Note that a precursor which is vaporized by a vaporization device (also referred to as a vaporizer or a bubbling device) can be used.

Note that a plurality of substances can be used for the first element. In the repeated first steps, different substances can be used for the first element.

For example, a variety of substances which react with the first element, which is selected in accordance with the kind of a reaction product to be deposited and the first element, can be used for the second element. For example, a substance which contributes to an oxidation reaction, a substance which contributes to a reduction reaction, a substance which contributes to an addition reaction, a substance which contributes to a decomposition reaction, a substance which contributes to a hydrolysis reaction, or the like can be used for the second element.

Note that plasma can be used for the second element. Specifically, an oxygen radical, a nitrogen radical, or the like can be used for the second element. Accordingly, the reaction speed of the first element can be raised. Thus, the temperature of the process member can be suppressed. Moreover, the deposition time can be shortened.

### <Structure Example 2 of Display Module>

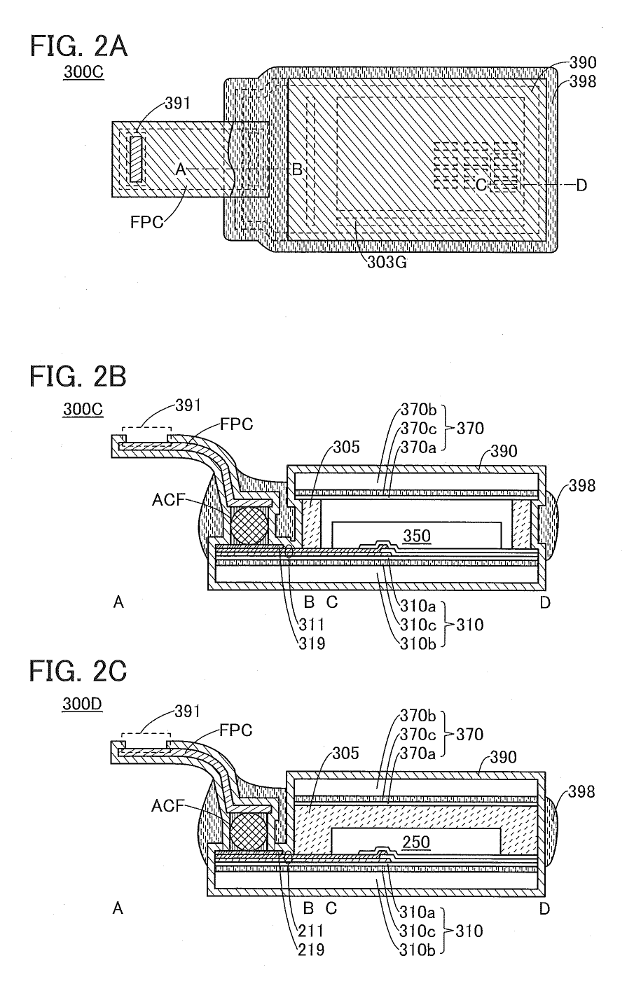

Another structure of a display module of one embodiment of the present invention will be described with reference to FIGS. 2A to 2C.

FIGS. 2A to 2C illustrate the structure of the display module of one embodiment of the present invention. FIG. 2A is a top view of a display module 300C of one embodiment of the present invention, and FIG. 2B is a cross-sectional view taken along the lines A-B and C-D in FIG. 2A.

FIG. 2C is a cross-sectional view illustrating a structure of a display module 300D which has a structure different from the display module 300C illustrated in FIG. 2B.

Note that the display module 300C is different from the display module 300 described with reference to FIG. 1B in that a resin layer 398 is included. Different structures will be described in detail below, and the above description is referred to for the other similar structures.

In contrast, the display module 300D described with reference to FIG. 2C is different from the display module 300C described with reference to FIG. 2B in that a region between the display element 350 and the second base 370 is filled with the bonding layer 305.

The display module 300C described in this embodiment is the display module 300 including the resin layer 398. In addition, the insulating layer 390 includes a region interposed between the bonding layer 305 and the resin layer 398.

The display module 300C described in this embodiment includes the insulating layer 390 which is interposed between the bonding layer 305 and the resin layer 389. Accordingly, various kinds of stresses are dispersed and therefore breakage of the insulating layer due to stress concentration can be prevented. Thus, a novel, highly convenient or reliable display module can be provided.

### <<Display Module 300C>>

The display module 300C includes the resin layer 398, the terminal 319, the first base 310, the second base 370, the bonding layer 305, the display element 350, the flexible printed circuit FPC, or the insulating layer 390.

The display module 300C includes the wiring 311.

### <<Resin Layer 398>>

The display module 300C includes the resin layer 398 so that the insulating layer 390 has a region interposed between the resin layer 398 and the bonding layer 305.

For example, a material similar to the material which can be used for the bonding layer 305 can be used for the resin layer 398.

This embodiment can be combined with any of the other embodiments and examples in this specification as appropriate.

### Embodiment 2

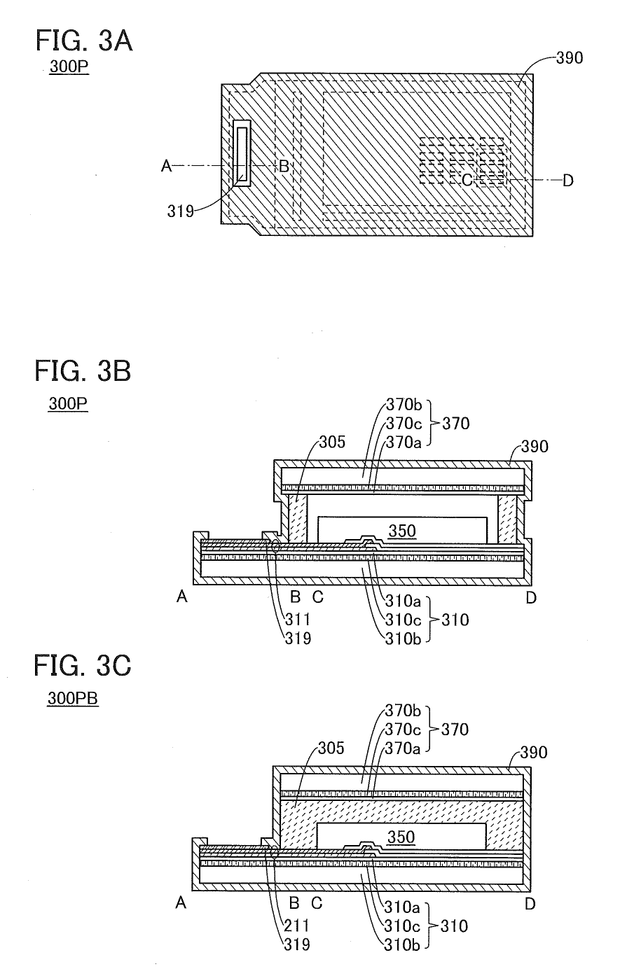

In this embodiment, a structure of a display panel of one embodiment of the present invention will be described with reference to FIGS. 3A to 3C.

FIGS. 3A to 3C illustrate the structure of the display panel of one embodiment of the present invention. FIG. 3A is a top view of a display panel 300P of one embodiment of the present invention, and FIG. 3B is a cross-sectional view taken along the lines A-B and C-D in FIG. 3A.

FIG. 3C is a cross-sectional view illustrating a structure of a display panel 300PB which has structure different from the display panel 300P illustrated in FIG. 3B.

### <Structure Example 1 of Display Panel>

The display panel 300P described in this embodiment includes the terminal 319, the first base 310 which is flexible and supports the terminal 319, the second base 370 which is flexible and has a region overlapping with the first base 310, the bonding layer 305 which bonds the first base 310 and the second base 370, the display element 350 which is provided between the first base 310 and the second base 370 and is electrically connected to the terminal 319, and an insulating layer 390 in contact with the first base 310, the second base 370, and the bonding layer 305 (see FIG. 3B).

Accordingly, it is possible to suppress impurity diffusion to a region surrounded by the first base, the second base, and the insulating layer. Thus, a novel, highly convenient or reliable display panel can be provided.

The display panel 300P includes the wiring 311 electrically connected to the terminal 319 and the display element 350.

Note that the display panel 300P described with reference to FIG. 3B has a region which includes a material different from the material of the bonding layer 305 between the display element 350 and the second base 370. For example, the display panel 300P has a region which includes gas, liquid, liquid crystal, or the like.

In contrast, the display panel 300PB described with reference to FIG. 3C is different from the display panel 300P described with reference to FIG. 3B in that a region between the display element 350 and the second base 370 is filled with the bonding layer 305.

Note that the display panel 300P is different from the display modules described with reference to FIGS. 1A to 1C in that the flexible printed circuit FPC is not included and the insulating layer 390 has an opening in a region overlapping with the terminal 319. For example, the opening can be formed in such a manner that the insulating layer is formed on a process member in which a mask is formed in a region overlapping with the terminal 319 and then part of the insulating layer is removed together with the mask by a lift-off method.

### <Structure Example 2 of Display Panel>

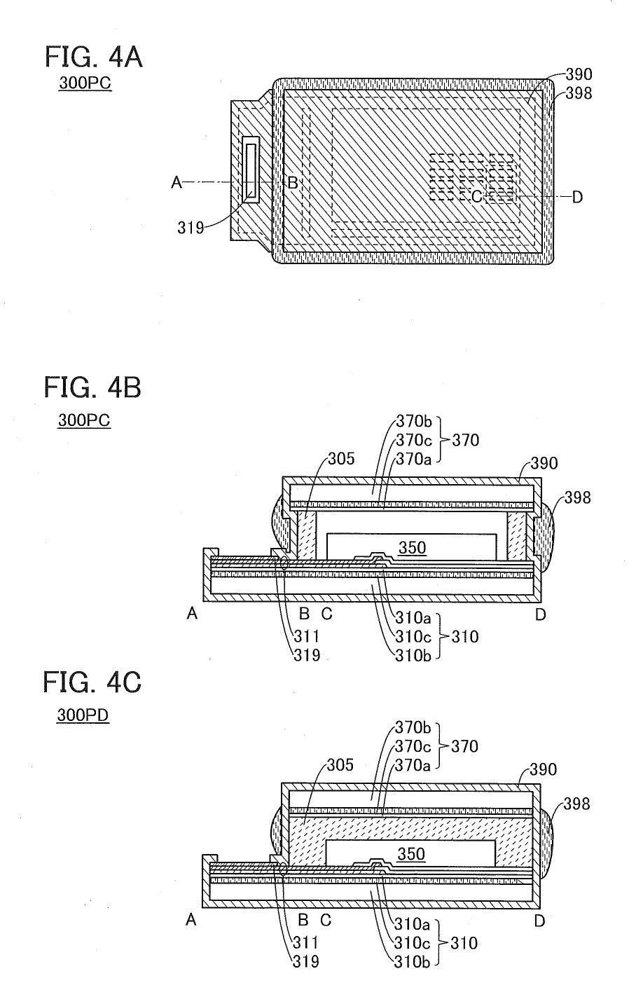

Another structure of a display panel of one embodiment of the present invention will be described with reference to FIGS. 4A to 4C.

FIGS. 4A to 4C illustrate the structure of the display panel of one embodiment of the present invention. FIG. 4A is a top view of a display panel 300PC of one embodiment of the present invention, and FIG. 4B is a cross-sectional view taken along the lines A-B and C-D in FIG. 4A.

FIG. 4C is a cross-sectional view illustrating a structure of a display panel 300PD which has a structure different from the display panel 300PC illustrated in FIG. 4B.

Note that the display panel 300PC is different from the display panel 300P described with reference to FIG. 3B in that the resin layer 398 is included. Different structures will be described in detail below, and the above description is referred to for the other similar structures.

In contrast, the display panel 300PD described with reference to FIG. 4C is different from the display panel 300PC described with reference to FIG. 4B in that a region between the display element 350 and the second base 370 is filled with the bonding layer 305.

The display panel 300PC described in this embodiment is the display panel 300P including the resin layer 398. In addition, the insulating layer 390 includes a region interposed between the bonding layer 305 and the resin layer 398.

The display panel 300PC described in this embodiment includes the insulating layer 390 which is interposed between the bonding layer 305 and the resin layer 389. Accordingly, various kinds of stresses are dispersed and therefore breakage of the insulating layer due to stress concentration can be prevented. Thus, a novel, highly convenient or reliable display panel can be provided.

### <<Display Panel 300PC>>

The display panel 300PC includes the resin layer 398, the terminal 319, the first base 310, the second base 370, the bonding layer 305, the display element 350, or the insulating layer 390.

The display panel 300PC includes the wiring 311.

### <<Resin Layer 398>>

The display panel 300PC includes the resin layer 398 so that the insulating layer 390 has a region interposed between the resin layer 398 and the bonding layer 305.

For example, a material similar to the material which can be used for the bonding layer 305 can be used for the resin layer 398.

This embodiment can be combined with any of the other embodiments and examples in this specification as appropriate.

### Embodiment 3

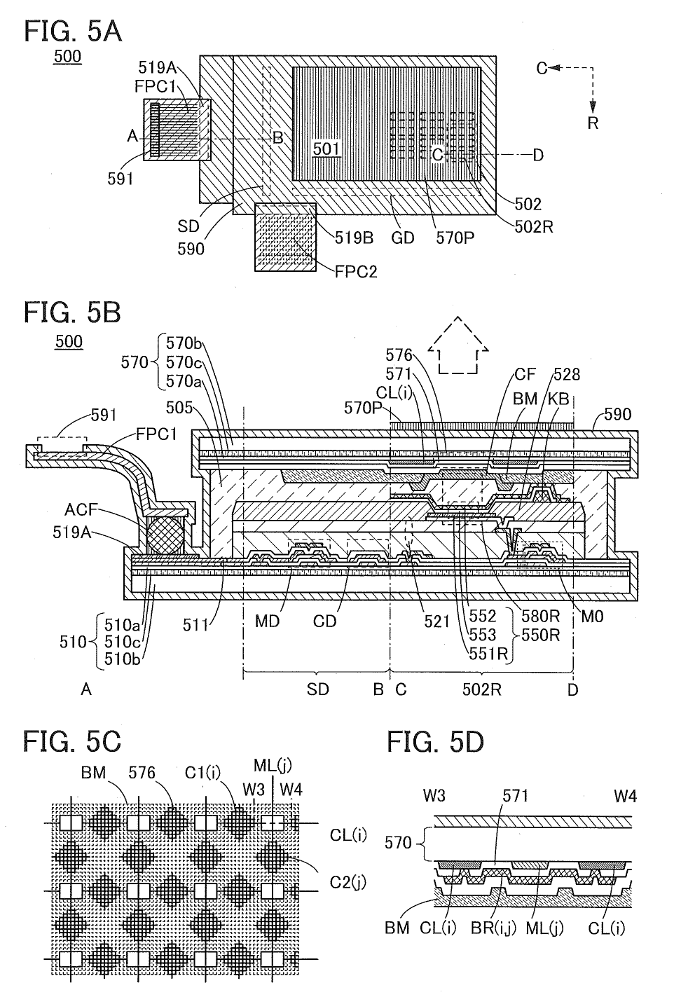

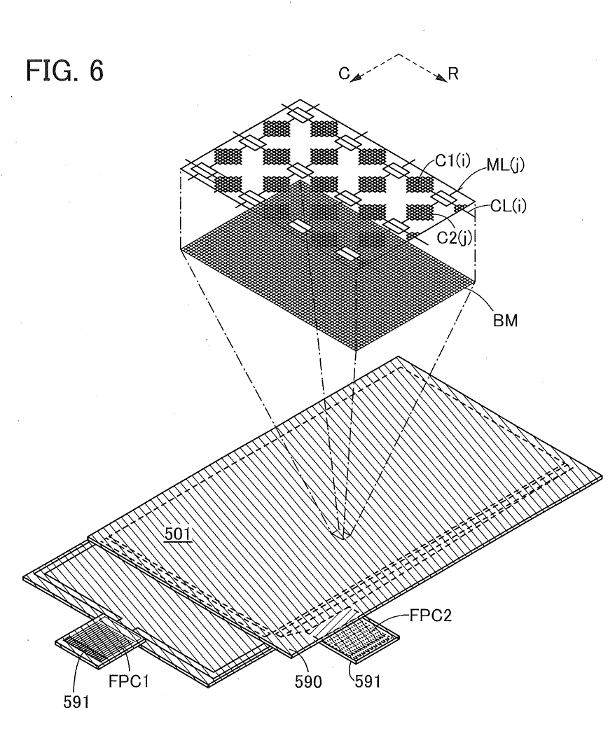

In this embodiment, a structure of a display module of one embodiment of the present invention which can be used for an input/output device will be described with reference to FIGS. 5A to 5D and FIG. 6.

FIGS. 5A to 5D and FIG. 6 illustrate the structure of the display module of one embodiment of the present invention.

Note that FIG. 5A is a top view of a display module 500 of one embodiment of the present invention, and FIG. 5B is a cross-sectional view taken along the lines A-B and C-D in FIG. 5A. FIG. 5C is a top view illustrating a structure of part of the display module 500, and FIG. 5D is a cross-sectional view taken along the line W3-W4 in FIG. 5C.

FIG. 6 is a projection view illustrating the display module 500 of one embodiment of the present invention. Note that for convenience of description, part of the display module 500 is enlarged.

### <Structure Example 1 of Display Module>

The display module 500 described in this embodiment includes a first terminal portion 519A, a first base 510 which supports the first terminal portion 519A, a second base 570 which has a region overlapping with the first base 510 and includes a second terminal portion 519B, and a bonding layer 505 which has a function of bonding the first base 510 and the second base 570 (see FIG. 5B).

The display module 500 of one embodiment of the present invention includes a display portion. The display portion includes a display element 550R between the first base 510 and the second base 570, the first terminal portion 519A electrically connected to the display element 550R, and a first flexible printed circuit FPC1 electrically connected to the first terminal portion 519A.

The display module 500 of one embodiment of the present invention further includes a sensing portion. The sensing portion includes a touch sensor between the first base 510 and the second base 570, the second terminal portion 519B electrically connected to the touch sensor, and a second flexible printed circuit FPC2 electrically connected to the second terminal portion 519B (see FIG. 5A).

The display module 500 of one embodiment of the present invention further includes an insulating layer 590 in contact with the first base 510, the second base 570, the bonding layer 505, the flexible printed circuit FPC1, and the flexible printed circuit FPC2 (see FIG. 5B).

Note that the insulating layer 590 has an opening 591 in a region overlapping with a terminal of the flexible printed circuit FPC1 and a region overlapping with a terminal of the flexible printed circuit FPC2. Note that an insulating layer which has a region overlapping with the display portion or the sensing portion can be used as the insulating layer 590. Particularly when a material having higher hardness than that of the first base 510 is used for the insulating layer 590, the surface of the display module can be hardly damaged when in use.

### <<Display Portion>>

The display module 500 of one embodiment of the present invention further includes a pixel 502 supplied with a control signal and an image signal, a region 501 in which the pixels 502 are arranged, a driver circuit GD which supplies the control signal, a driver circuit SD which supplies the image signal, a wiring 511 electrically connected to the driver circuit SD, and the first terminal portion 519A electrically connected to the wiring 511 (see FIGS. 5A and 5B).

The pixel 502 includes a plurality of subpixels (e.g., subpixel 502R). Note that subpixels which have a function of displaying a variety of colors can be used. Specifically, a subpixel which has a function of displaying red can be used as the subpixel 502R. Moreover, subpixels which have a function of displaying green, blue, and the like can be used for the pixel 502.

The subpixel 502R includes the display element 550R, a coloring layer CF which has a region overlapping with the display element 550R, and a pixel circuit which has a function of supplying electric power to the display element 550R in response to the control signal and the image signal. For example, a driving transistor M0 or a capacitor can be used for the pixel circuit (see FIG. 5B).

The display element 550R includes a first electrode 551R and a second electrode 552 which are supplied with electric power, and a layer 553 containing a light-emitting organic compound between the first electrode 551R and the second electrode 552.

The first electrode 551R is electrically connected to a source electrode or a drain electrode of the driving transistor M0.

The driver circuit SD includes a transistor MD or a capacitor CD. For example, a transistor which can be formed in the same process as the driving transistor M0 can be used as the transistor MD.

The display module 500 of one embodiment of the present invention includes the pixel circuit between the layer 553 containing a light-emitting organic compound and the first base 510 and an insulating layer 521 between the layer 553 containing a light-emitting organic compound and the pixel circuit.

The display module 500 of one embodiment of the present invention further includes a light-blocking layer BM having an opening in a region overlapping with the subpixel 502R.

Furthermore, the display module 500 of one embodiment of the present invention includes a functional film 570P which has a region overlapping with the region 501. For example, a polarizing plate can be used for the functional film 570P.

### <<Sensing Portion>>

The display module 500 of one embodiment of the present invention further includes a touch sensor including a sensing element.

A control line CL(i) electrically connected to the touch sensor, a signal line ML(j) electrically connected to the touch sensor, a terminal electrically connected to the control line CL(i), and a second terminal portion 519B electrically connected to the signal line ML(j) are included (see FIG. 5C and FIG. 6).

The touch sensor includes a first electrode C1(i) and a second electrode C2(j) which does not partly overlap with the first electrode C1(i).

The first electrode C1(i) or the second electrode C2(j) includes a conductive film in which regions overlapping with the pixels 502 or the subpixels 502R includes regions having light-transmitting properties.

Alternatively, the first electrode C1(i) or the second electrode C2(j) includes a net-like conductive film having openings 576, in a portion overlapping with the pixels 502 or the subpixels 502R.

The first electrode C1(i) is electrically connected to the control line CL(i) extended in a row direction (a direction indicated by an arrow R in FIG. 6). Note that the control line CL(i) has a function of supplying a control signal.

The second electrode C2(j) is electrically connected to the signal line ML(j) extended in a column direction (a direction indicated by an arrow C in FIG. 6). Note that the signal line ML(j) has a function of supplying a sensor signal (see FIG. 6).

The control line CL(i) includes a wiring BR(i,j). In the wiring BR(i,j), the control line CL(i) intersects with the signal line ML(j) (see FIG. 5C). An insulating layer 571 is provided between the wiring BR(i,j) and the signal line ML(j) (see FIG. 5D). Thus, a short circuit between the wiring BR(i,j) and the signal line ML(j) can be prevented.

The display module 500 described in this embodiment includes the display element including the layer 533 containing a light-emitting organic compound in a region surrounded by the first base 510, the second base 570, and the insulating layer 590. Accordingly, it is possible to suppress diffusion of various impurities to the layer 553 containing a light-emitting organic compound. Thus, a novel, highly convenient or reliable display module can be provided.

Note that the display module 500 including the touch sensor can be referred to as an input/output module or a touch panel module.

The display module 500 can sense a near object and supply positional data of the approaching object or sensing data including the track or the like. For example, a user of the display module 500 can make a variety of gestures (e.g., tap, drag, swipe, and pinch in) to be sensed using his/her finger or the like that approaches or is in contact with the display module 500 as a pointer.

In addition, the user of the display module 500 can supply a variety of operation instructions to an arithmetic device with the display module 500. For example, the display module 500 can sense a gesture, an arithmetic device can determine whether or not the sensing data supplied from the display module 500 satisfies a predetermined condition on the basis of a program or the like, and a predetermined instruction can be executed in the case where the condition is satisfied.

Individual components included in the display module 500 will be described below. Note that these components cannot be clearly distinguished from each other and one component also serves as another component or includes part of another component in some cases.

For example, the display module 500 serves as a sensing panel or a display panel as well as a touch panel.

### <<Overall Structure>>

The display module 500 described in this embodiment includes the first base 510, the second base 570, the bonding layer 505, the display element 550R, the first terminal portion 519A, the second terminal portion 519B, the insulating layer 590, the flexible printed circuit FPC1, the flexible printed circuit FPC2, or a functional layer.

The display module 500 further includes the pixel 502, the region 501, the driver circuit GD, the driver circuit SD, the wiring 511, the subpixel 502R, the display element 550R, the coloring layer CF, the pixel circuit, the driving transistor M0, the first electrode 551R, the second electrode 552, the layer 553 containing a light-emitting organic compound, the transistor MD, the capacitor CD, the light-blocking layer BM, and the functional film 570P.

The display module 500 further includes the touch sensor, the control line CL(i), the signal line ML(j), the first electrode C1(i), and the second electrode C2(j).

### <<First Base>>

A variety of bases can be used as the first base 510.

In this specification and the like, a transistor can be formed using any of a variety of substrates or any of a variety of bases, for example. The type of a substrate or a base is not limited to a certain type. Examples of the substrate or base include a semiconductor substrate (e.g., a single crystal substrate or a silicon substrate), an SOI substrate, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, an attachment film, paper including a fibrous material, a base film, and the like. As an example of a glass substrate, a barium borosilicate glass substrate, an aluminoborosilicate glass substrate, a soda lime glass substrate, and the like can be given. Examples of the flexible substrate, the attachment film, the base film, and the like are substrates of plastics typified by polyethylene terephthalate (PET), polyethylene naphthalate (PEN), polyether sulfone (PES), and polytetrafluoroethylene (PTFE). Another example is a synthetic resin such as acrylic. Furthermore, polypropylene, polyester, polyvinyl fluoride, and polyvinyl chloride can be given as examples. Other examples are polyamide, polyimide, aramid, epoxy, an inorganic vapor deposition film, paper, and the like. Specifically, the use of semiconductor substrates, single crystal substrates, SOI substrates, or the like enables the manufacture of small-sized transistors with a small variation in characteristics, size, shape, or the like and with high current capability. A circuit using such transistors achieves lower power consumption of the circuit or higher integration of the circuit.

Alternatively, a flexible substrate may be used as the substrate such that the transistor is provided directly on the flexible substrate. Further alternatively, a separation layer may be provided between the substrate and the transistor. The separation layer can be used when part or the whole of a semiconductor device formed over the separation layer is separated from the substrate and transferred onto another substrate. In such a case, the transistor can be transferred to a substrate having low heat resistance or a flexible substrate as well. For the above separation layer, a stack including inorganic films, which are a tungsten film and a silicon oxide film, or a structure in which an organic resin film of polyimide or the like is formed over a substrate can be used, for example.

In other words, after the transistor is formed using a substrate, the transistor may be transferred to another substrate. Examples of a substrate to which a transistor is transferred include, in addition to the above substrate over which the transistor can be formed, a paper substrate, a cellophane substrate, an aramid film substrate, a polyimide film substrate, a stone substrate, a wood substrate, a cloth substrate (including a natural fiber (e.g., silk, cotton, or hemp), a synthetic fiber (e.g., nylon, polyurethane, or polyester), a regenerated fiber (e.g., acetate, cupra, rayon, or regenerated polyester), and the like), a leather substrate, a rubber substrate, and the like. When such a substrate is used, a transistor with excellent characteristics or a transistor with low power consumption can be formed, a device with high durability can be formed, high heat resistance can be provided, or reduction in weight or thickness can be achieved.

In this specification and the like, for example, transistors with a variety of structures can be used as a transistor, without limitation to a certain type. For example, a transistor including a single crystal silicon or a non-single-crystal semiconductor film typified by amorphous silicon, polycrystalline silicon, microcrystalline (also referred to as microcrystal, nanocrystal, or semi-amorphous) silicon, or the like can be used as a transistor. Alternatively, a thin film transistor (TFT) formed using the above semiconductor as thin films can be used. In the case of using the TFT, there are a variety of advantages. For example, since the TFT can be formed at temperature lower than that of the case of using single crystal silicon, manufacturing cost can be reduced or a manufacturing apparatus can be made larger. Since the manufacturing apparatus can be made larger, the TFT can be formed using a large substrate. Therefore, many display devices can be formed at the same time at low cost. In addition, a substrate having low heat resistance can be used because of low manufacturing temperature. Therefore, the transistor can be formed using a light-transmitting substrate. Alternatively, transmission of light in a display element can be controlled by using the transistor formed using the light-transmitting substrate. Alternatively, part of a film included in the transistor can transmit light because of a small thickness of the transistor. Therefore, the aperture ratio can be improved.

Note that when a catalyst (e.g., nickel) is used in the case of forming polycrystalline silicon, crystallinity can be further improved and a transistor having excellent electric characteristics can be formed. Accordingly, a gate driver circuit (e.g., a scan line driver circuit), a source driver circuit (e.g., a signal line driver circuit), and a signal processing circuit (e.g., a signal generation circuit, a gamma correction circuit, or a DA converter circuit) can be formed using the same substrate.

Note that when a catalyst (e.g., nickel) is used in the case of forming microcrystalline silicon, crystallinity can be further improved and a transistor having excellent electric characteristics can be formed. In that case, crystallinity can be improved by just performing heat treatment without performing laser irradiation. Accordingly, a gate driver circuit (e.g., a scan line driver circuit) and part of a source driver circuit (e.g., an analog switch) can be formed over the same substrate. Note that when laser irradiation for crystallization is not performed, unevenness in crystallinity of silicon can be suppressed. Therefore, high-quality images can be displayed. Note that it is possible to form polycrystalline silicon or microcrystalline silicon without a catalyst (e.g., nickel).

Note that although the crystallinity of silicon is preferably improved to polycrystal, microcrystal, or the like in the whole panel, the present invention is not limited to this. The crystallinity of silicon may be improved only in part of the panel. Selective increase in crystallinity can be achieved by selective laser irradiation or the like. For example, only a peripheral circuit region excluding pixels may be irradiated with laser light. Alternatively, only a region of a gate driver circuit, a source driver circuit, or the like may be irradiated with laser light. Alternatively, only part of a source driver circuit (e.g., an analog switch) may be irradiated with laser light. Accordingly, the crystallinity of silicon can be improved only in a region in which a circuit needs to be operated at high speed. Because a pixel region is not particularly needed to be operated at high speed, even if crystallinity is not improved, the pixel circuit can be operated without any problem. Thus, a region whose crystallinity is improved is small, so that manufacturing steps can be shortened. This can increase throughput and reduce manufacturing cost. Alternatively, since the number of necessary manufacturing apparatus is small, manufacturing cost can be reduced.

Examples of the transistor include a transistor including a compound semiconductor (e.g., SiGe or GaAs) or an oxide semiconductor (e.g., Zn—O, In—Ga—Zn—O, In—Zn—O, In—Sn—O (ITO), Sn—O, Ti—O, Al—Zn—Sn—O (AZTO), or In—Sn—Zn—O) and a thin film transistor including a thin film of such a compound semiconductor or an oxide semiconductor. Because manufacturing temperature can be lowered, such a transistor can be formed at room temperature, for example. The transistor can thus be formed directly on a substrate having low heat resistance, such as a plastic substrate or a film substrate. Note that such a compound semiconductor or an oxide semiconductor can be used not only for a channel portion of the transistor but also for other applications. For example, such a compound semiconductor or an oxide semiconductor can be used for a wiring, a resistor, a pixel electrode, a light-transmitting electrode, or the like. Such an element can be formed at the same time as the transistor; thus, cost can be reduced.

Note that for example, a transistor formed by an ink-jet method or a printing method can be used as a transistor. Accordingly, such a transistor can be formed at room temperature, can be formed at a low vacuum, or can be formed using a large substrate. Thus, the transistor can be formed without using a mask (reticle), which enables the layout of the transistor to be easily changed. Alternatively, the transistor can be formed without using a resist, leading to reductions in material cost and the number of steps. Further, since a film can be formed only in a portion where the film is needed, a material is not wasted as compared with the case of employing a manufacturing method by which etching is performed after the film is formed over the entire surface, so that the cost can be reduced.

Note that for example, a transistor including an organic semiconductor or a carbon nanotube can be used as a transistor. Thus, such a transistor can be formed over a flexible substrate. A device including a transistor which includes an organic semiconductor or a carbon nanotube can resist a shock.

Note that transistors with a variety of different structures can be used as a transistor. For example, a MOS transistor, a junction transistor, a bipolar transistor, or the like can be used as a transistor. By using a MOS transistor as a transistor, the size of the transistor can be reduced. Thus, a number of transistors can be mounted. By using a bipolar transistor as a transistor, a large amount of current can flow. Thus, a circuit can be operated at high speed. Note that a MOS transistor and a bipolar transistor may be formed over one substrate, in which case reductions in power consumption and size, high-speed operation, and the like can be achieved.

For example, a material similar to the material which can be used for the first base 310 described in Embodiment 1 can be used.

### <<Second Base>>

A variety of bases can be used as the second base 570.

For example, a material similar to the material which can be used for the second base 370 described in Embodiment 1 can be used.

### <<Bonding Layer>>

A variety of materials can be used for the bonding layer.

For example, a material similar to the material which can be used for the bonding layer 305 described in Embodiment 1 can be used.

### <<Wiring or Terminal>>

The wiring or the terminal has a function of supplying an image signal, a control signal, a sensor signal, a power supply potential, or the like. The wiring includes the control line CL(i), the signal line ML(j), and the like.

A variety of materials can be used for the wiring.

For example, a material similar to the material which can be used for the wiring 311 or the terminal 319 described in Embodiment 1 can be used.

### <<Display Unit>>

A display unit 580R includes the display element 550R or the coloring layer CF which transmits at least part of light.

A spacer KB is provided between the display element 550R and the coloring layer CF. The spacer KB has a function of controlling a distance between the display element 550R and the coloring layer CF.

For example, a layer containing a material such as a pigment or a dye can be used as the coloring layer CF. Thus, it is possible to provide a display unit which displays a specific color of light transmitted through the coloring layer CF.

A microcavity structure which includes a reflective film and a semi-transmissive and semi-reflective film can be used for the display unit 580R.

Specifically, a light-emitting element including a reflective conductive film as one electrode, a semi-transmissive and semi-reflective conductive film as the other electrode, and a layer containing a light-emitting organic compound between the two electrodes can be used for the display unit 580R.

For example, a microresonator for extracting red light efficiently and a coloring layer which transmits red light may be used in the display unit 580R for displaying red, a microresonator for extracting green light efficiently and a coloring layer which transmits green light may be used in a display unit for displaying green, a microresonator for extracting blue light efficiently and a coloring layer which transmits blue light may be used in a display unit for displaying blue light, or a microresonator for extracting yellow light efficiently and a coloring layer which transmits yellow light may be used in a display unit for displaying yellow light.

### <<Display Element>>

Display media whose contrast, luminance, reflectance, transmittance, or the like is changed by an electrical or magnetic effect can be used as a display element 550R.

For example, an organic EL element which emits white light can be used.

For example, a plurality of organic EL elements which emit light of different colors can be used.

For example, a partition wall 528 for dividing the display element into a plurality of display elements can be used. For example, an insulating material can be used for the partition wall 528. Specifically, an insulating inorganic oxide material, a resin, or the like can be used.

Note that an electroluminescence (EL) element (e.g., an EL element including organic and inorganic materials, an organic EL element, or an inorganic EL element), an LED (e.g., a white LED, a red LED, a green LED, or a blue LED), a transistor (a transistor which emits light depending on current), an electron emitter, a liquid crystal element, electronic ink, an electrophoretic element, a grating light valve (GLV), a plasma display panel (PDP), a display element using micro electro mechanical systems (MEMS), a digital micromirror device (DMD), a digital micro shutter (DMS), MIRASOL (registered trademark), an interferometric modulator (IMOD) element, a MEMS shutter display element, an optical-interference-type MEMS display element, an electrowetting element, or the like can be used.

### <<First Electrode>>

A conductive material can be used for the first electrode 551R. In particular, a material which efficiently reflects light emitted from the layer 553 containing a light-emitting organic compound is preferable.

For example, an inorganic conductive material, an organic conductive material, a metal material, a conductive ceramic material, or the like can be used. Note that a structure of a single layer or stacked layers including a material selected from the above materials can be used, for example.

Specifically, a metal element selected from aluminum, gold, platinum, silver, chromium, tantalum, titanium, molybdenum, tungsten, nickel, iron, cobalt, palladium, and manganese; an alloy including any of the above-described metal elements; an alloy including any of the above-described metal elements in combination; or the like can be used.

In particular, silver, aluminum, and an alloy including any of them are preferable because of their high reflectance with respect to visible light.

Alternatively, a conductive oxide such as indium oxide, indium tin oxide, indium zinc oxide, zinc oxide, or zinc oxide to which gallium is added can be used.

Alternatively, graphene or graphite can be used. The film including graphene can be formed, for example, by reducing a film including graphene oxide. As a reducing method, a method using heat, a method using a reducing agent, or the like can be employed.

Alternatively, a conductive high molecule can be used.

### <<Second Electrode>>

A light-transmitting conductive material can be used for the second electrode 552.

For example, a material which can be used for the first electrode 551R is made thin enough to have a light-transmitting property to be used for the second electrode 552. Specifically, a metal thin film with a thickness greater than or equal to 5 nm and less than or equal to 30 nm can be used.

Note that a single layer or stacked layers can include any of the above materials. Specifically, a stack of silver with a thickness greater than or equal to 5 nm and less than or equal to 30 nm and a metal oxide layer including indium and tin can be used.

### <<Layer Containing Light-Emitting Organic Compound>>

A layer containing an organic compound which emits fluorescence or light obtained through a triplet excited state can be used as the layer 553 containing a light-emitting organic compound.

A structure of a single layer or stacked layers can be used for the layer 553 containing a light-emitting organic compound.

For example, a layer including a material with a higher hole-transport property than an electron-transport property, a layer including a material with a higher electron-transport property than a hole-transport property, or the like can be used.

For example, a plurality of layers 553 containing light-emitting organic compounds with different compositions can be used in a display panel. For example, the display panel can include a layer containing a red light-emitting organic compound, a layer containing a green light-emitting organic compound, and a layer containing a blue light-emitting organic compound.

A light-emitting element includes a light-emitting substance between a pair of electrodes. Examples of the light-emitting substance include a material which can convert the singlet excitation energy into light emission (e.g., a fluorescent material) and a material which can convert the triplet excitation energy into light emission (e.g., a phosphorescent material or a thermally activated delayed fluorescence (TADF) material).

The above-described light-emitting substance has a peak of an emission spectrum in at least any one of blue (greater than or equal to 420 nm and less than 500 nm), green (greater than or equal to 500 nm and less than 550 nm), yellow (greater than or equal to 550 nm and less than 600 nm), and red (greater than or equal to 600 nm and less than or equal to 740 nm) wavelength ranges. Note that the above-described light-emitting substance can be formed by an evaporation method (including a vacuum evaporation method), an ink-jet method, a coating method, gravure printing, or the like.

Examples of a substance which has a peak of an emission spectrum in a blue wavelength range include fluorescent materials containing a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, a naphthalene derivative, and the like. A pyrene derivative is particularly preferable because it has a high emission quantum yield.

As the substance which has a peak of an emission spectrum in a blue wavelength range, for example, an iridium-, rhodium-, or platinum-based organometallic complex or a metal complex can be used; in particular, an organoiridium complex such as an iridium-based ortho-metalated complex is preferable. As an ortho-metalated ligand, a 4H-triazole ligand, a 1H-triazole ligand, an imidazole ligand, a pyridine ligand, and the like can be given. The substance which has a peak of an emission spectrum in a blue wavelength range includes, for example, an organometallic iridium complex which includes an iridium metal, a ligand coordinated to the iridium metal, and a substituent bonded to the ligand, and in which the substituent is a bridged cyclic hydrocarbon group (e.g., an adamantyl group or a norbornyl group) whose mass number is greater than or equal to 90 and less than 200. Moreover, the above-described ligand is preferably a nitrogen-containing five-membered heterocyclic skeleton (e.g., an imidazole skeleton or a triazole skeleton). When a substance including the above-described nitrogen-containing five-membered heterocyclic skeleton is used for a light-emitting layer, a light-emitting element having high emission efficiency or high reliability can be obtained.

As the substances which have peaks of emission spectra in green, yellow, and red wavelength ranges, an iridium-, rhodium-, or platinum-based organometallic complex or a metal complex can be used; in particular, an organoiridium complex such as an iridium-based ortho-metalated complex is preferable. As an ortho-metalated ligand, a 4H-triazole ligand, a 1H-triazole ligand, an imidazole ligand, a pyridine ligand, a pyrimidine ligand, a pyrazine ligand, an isoquinoline ligand, and the like can be given. As the metal complex, a platinum complex having a porphyrin ligand, and the like can be given. Further, the organometallic iridium complex having a pyrazine ligand is preferable because red light emission with favorable chromaticity can be provided. Moreover, the organometallic iridium complex having a pyrimidine ligand has high reliability or emission efficiency and is thus preferable.

The light-emitting element may include a substance with a carrier (electron or hole)-transport property in addition to the above-described light-emitting substance. Besides the above-described light-emitting substance, an inorganic compound or a high molecular compound (e.g., an oligomer, a dendrimer, or a polymer) may be included in the light-emitting element.

However, as an effect of heating the layer 553 containing a light-emitting organic compound after its formation, the layer 553 containing a light-emitting organic compound can be stable in some cases.

For example, the layer 553 containing a light-emitting organic compound is stabilized by applying heat thereto when the insulating layer 590 is formed. Thus, the reliability of the display element 550R can be improved.

### <<Flexible Printed Circuit>>

Flexible printed circuits of a variety of structures can be used for the flexible printed circuit FPC1 or FPC2.

For example, a structure similar to the structure which can be used for the flexible printed circuit described in Embodiment 1 can be used.

### <<Insulating Layer>>

A variety of materials can be used for the insulating layer 590.

For example, a material similar to the material which can be used for the insulating layer 390 described in Embodiment 1 can be used.

For example, a material including an oxide, a nitride, a fluoride, a sulfide, a ternary compound, a metal, or a polymer can be used. Specifically, a film including an inorganic compound whose thickness is greater than or equal to 3 nm and less than or equal to 200 nm, preferably greater than or equal to 5 nm and less than or equal to 50 nm, can be used for the insulating layer 590.

For example, an inorganic material such as an oxide or a nitride with an atomic layer deposition method can be used. Specifically, aluminum oxide or the like can be used.

A material which has a function of suppressing diffusion of an impurity such as a water molecule can be used for the insulating layer 590. Thus, a decrease in the reliability of the display element 550R can be suppressed.

For example, diffusion of an impurity such as a water molecule to the layer 553 containing a light-emitting organic compound is suppressed, so that deterioration of the light-emitting organic compound can be suppressed.

Thus, the reliability of the display element 550R including the layer 553 containing a light-emitting organic compound can be improved.

### <<Sensing Element and Sensing Circuit>>

A sensing element for sensing capacitance, illuminance, magnetic force, a radio wave, pressure, or the like and supplying a signal based on the sensed physical quantity can be used for the functional layer.

For example, a conductive film, a photoelectric conversion element, a magnetic sensing element, a piezoelectric element, a resonator, or the like can be used as the sensing element.

For example, a sensing circuit having a function of supplying a signal which varies on the basis of the parasitic capacitance of a conductive film can be used for the functional layer. Thus, a finger or the like which approaches the conductive film in the air can be sensed with change in capacitance.

Specifically, a control signal is supplied to the first electrode C1(i) with the control line CL(i), and the potential of the second electrode C2 (j) which changes on the basis of the supplied control signal and the capacitance is obtained with the signal line ML(j) and can be supplied as a sensing signal.

For example, a circuit including a capacitor one electrode of which is connected to a conductive film can be used as a sensing circuit.

The sensing element may be formed by depositing a film for forming the sensing element over the second base 570 and processing the film.

Alternatively, the display module 500 may be formed in such a manner that part of the display module 500 is formed over another base, and the part is transferred to the second base 570.

### <<Functional Film>>

A variety of functional films can be used for the functional film 570P.

For example, an anti-reflective film or the like can be used for the functional film 570P. Specifically, an anti-glare coat, a circularly polarizing plate, or the like can be used. Thus, the intensity of outside light reflected when the display module 500 is used outdoors can be reduced, for example. Moreover, glare of lighting can be suppressed when used indoors, for example.

For example, a ceramic coat layer or a hard coat layer can be used as the functional film 570P. Specifically, a ceramic coat layer containing aluminum oxide, silicon oxide, or the like, a UV cured resin layer, or the like can be used.

### <Structure Example 2 of Display Module>

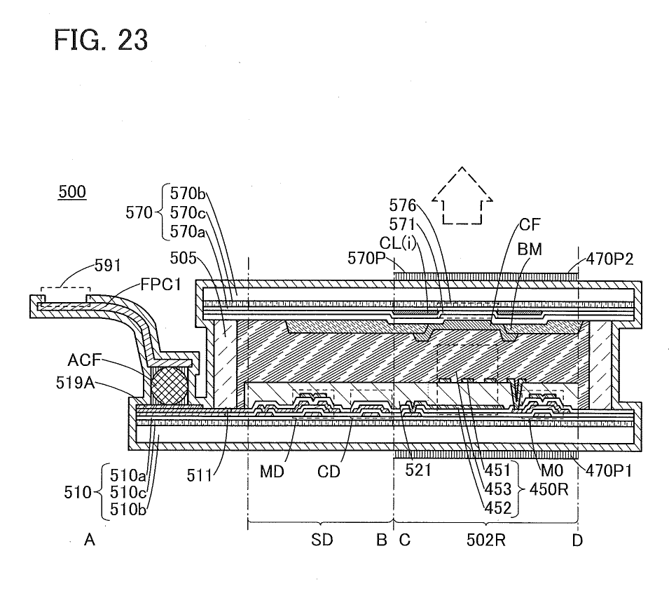

Another structure of a display module of one embodiment of the present invention will be described with reference to FIG. 23.

FIG. 23 is a cross-sectional view taken along the lines A-B and C-D in FIG. 2A.

Note that the display module described with reference to FIG. 23 is different from the display module 500 described with reference to FIG. 5B in that a display element 450R is included instead of the display element 550R and function films 470P1 and 470P2 are included. Different structures will be described in detail below, and the above description is referred to for the other similar structures.

### <<Display Element>>

A liquid crystal element using a variety of modes can be used for the display element 450R. Specifically, a liquid crystal element using any of the following modes can be used: an in-plane-switching (IPS) mode, a twisted nematic (TN) mode, a fringe field switching (FFS) mode, an axially symmetric aligned micro-cell (ASM) mode, an optically compensated birefringence (OCB) mode, a ferroelectric liquid crystal (FLC) mode, an antiferroelectric liquid crystal (AFLC) mode, or the like.

A liquid crystal material is selected in accordance with the mode used for the display element 450R, and arrangement of a first electrode 451 and a second electrode 452 is determined in accordance with the direction of an electric field applied to a layer 453 containing a liquid crystal material.

For example, a liquid crystal material such as a thermotropic liquid crystal, a low molecular liquid crystal, a high molecular liquid crystal, a ferroelectric liquid crystal, or an anti-ferroelectric liquid crystal can be used for the layer 453 containing a liquid crystal material.

For example, liquid crystal exhibiting a blue phase can be used. Thus, it is not necessary to use an alignment film. Moreover, a wide viewing angle can be obtained.

Furthermore, liquid crystal exhibiting a blue phase and a high molecule that stabilizes the blue phase can be used in combination. Thus, a temperature range where the liquid crystal exhibits the blue phase can be enlarged. Specifically, a mixture including the liquid crystal exhibiting the blue phase, a polymerization initiator, and monomers is injected or dropped and sealed between the substrates. After that, the monomers are polymerized, so that a temperature range where the liquid crystal exhibits the blue phase can be enlarged.

In addition, a polymer-dispersed liquid crystal (PDLC) can be used for the display element 450R.

For example, the first electrode 451 and the second electrode 452 which are arranged so that an electric field is applied perpendicularly can be used.

For example, the first electrode 451 and the second electrode 452 which are arranged so that an electric field is applied horizontally can be used.

### <<Insulating Layer>>

For example, a material which suppresses diffusion of an impurity such as moisture or an ionic substance to the layer 453 containing a liquid crystal material can be used for the insulating layer 590. Accordingly, a temporal reduction of voltage held between the first electrode 451 and the second electrode 452 can be suppressed.

Thus, the frequency of supplying an image signal to the display element 450R provided with the layer 453 containing a liquid crystal material and rewriting the image signal can be reduced without degrading display quality, resulting in reduction of power consumption.

Specifically, even when an image signal with a frequency lower than 60 Hz (e.g., lower than or equal to 30 Hz, preferably lower than or equal to 1 Hz) is supplied to the display element 450R, flickers which users recognize can be suppressed.

### <<Functional Film>>

A variety of functional films can be used for the functional film 470P1 or 470P2.

For example, an anti-reflective film or the like can be used for the functional film 470P1 or 470P2. Specifically, an anti-glare coat, a linearly polarizing plate, a circularly polarizing plate, or the like can be used. Thus, the intensity of outside light reflected when the display module 500 is used outdoors can be reduced, for example. Moreover, glare of external light can be suppressed when used indoors, for example.

For example, a ceramic coat layer or a hard coat layer can be used as the functional film 470P1 or 470P2. Specifically, a ceramic coat layer containing aluminum oxide, silicon oxide, or the like, a UV curable resin layer, or the like can be used.

This embodiment can be combined with any of the other embodiments and examples in this specification as appropriate.

### Embodiment 4

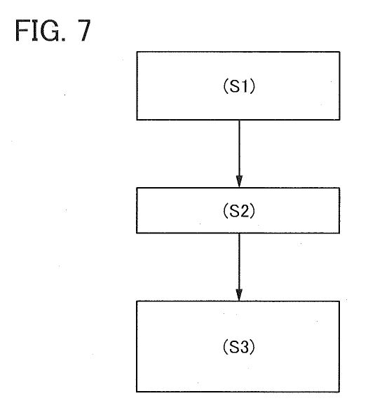

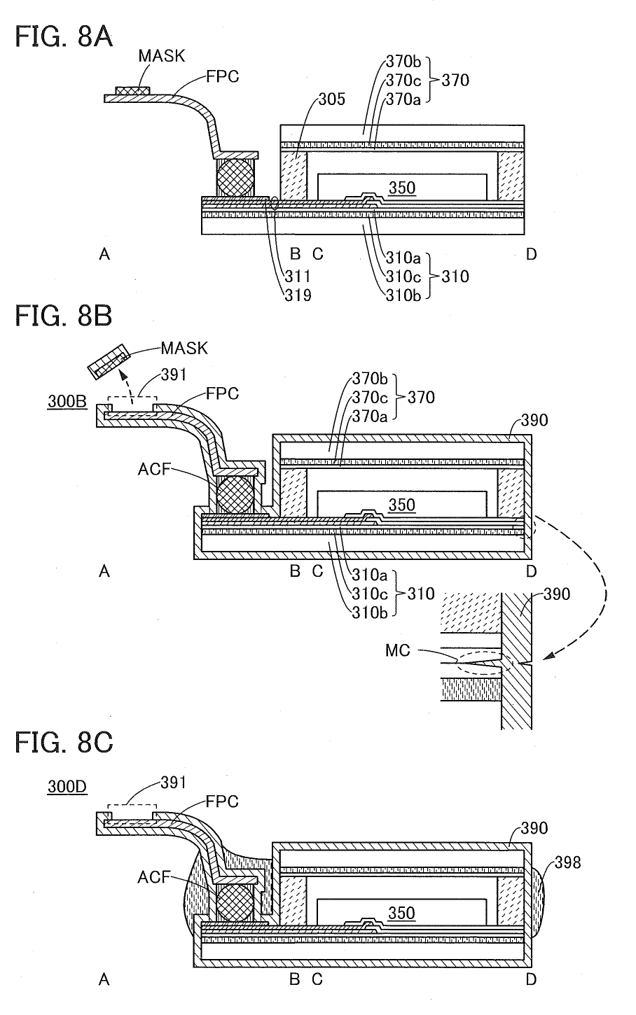

In this embodiment, a method for manufacturing a display module of one embodiment of the present invention will be described with reference to FIG. 7 and FIGS. 8A to 8C.

FIG. 7 is a flow chart showing the method for manufacturing the display module of one embodiment of the present invention.

FIGS. 8A to 8C illustrate the method for manufacturing the display module of one embodiment of the present invention. FIGS. 8A to 8C are cross-sectional views illustrating the display module during the manufacturing process.

### <Example of Method for Manufacturing Display Module>

A method for manufacturing the display module described in this embodiment includes the following three steps (see FIG. 7).

### <<First Step>>

In a first step, the terminal 319, a process member including the first base 310 which supports the terminal 319, the second base 370 which has a region overlapping with the first base 310, the bonding layer 305 which bonds the first base 310 and the second base 370, the display element 350 electrically connected to the terminal 319 between the first base 310 and the second base 370, and a flexible printed circuit FPC electrically connected to the terminal 319 is prepared, and a mask MASK is formed in a region overlapping with a terminal portion of the flexible printed circuit FPC (see S1 in FIG. 7 and FIG. 8A).

### <<Second Step>>

In a second step, the insulating layer 390 in contact with the first base 310, the second base 370, the bonding layer 305, and the flexible printed circuit FPC is formed by an atomic layer deposition method (see S2 in FIG. 7).

Meanwhile, defects such as cracks and pinholes included in the insulating layer 390 or unevenness in thickness of the insulating layer 390 might promote impurity diffusion. When an atomic layer deposition method is employed as a method of forming the insulating layer 390, defects included in the insulating layer 390 or unevenness in thickness of the insulating layer 390 can be reduced. Moreover, the insulating layer 390 can be formed dense. With the use of a resin or the like as a base film, the resin or the like is softened by heat and thus a film having good quality can be formed on the surface of the base film. Thus, the insulating layer 390 which can suppress impurity diffusion can be provided.

When the first base 310 or the second base 370 is divided from a base, a minute crack (also referred to as microcrack MC) might be generated on an end face of the base. Specifically, the base is scribed, and a minute crack might be generated on the end face of glass which is divided (also referred to as broken) by applying pressure so that pressure is concentrated at the scribed portion. When the insulating layer 390 is formed by an atomic layer deposition method, it is expected that a minute crack which is generated on the end face can be filled (see FIG. 8B).

For example, the insulating layer 390 can be formed by an atomic layer deposition method with a deposition apparatus 100 which will be described in Embodiment 5.

### <<Third Step>>

In a third step, part of the insulating layer 390 is removed together with the mask MASK and the opening 391 is formed in a region of the insulating layer 390 which overlaps with the terminal portion of the flexible printed circuit FPC (see S3 in FIG. 7 and FIG. 8B).

The method for manufacturing the display module described in this embodiment includes the first step of forming the mask MASK in a region overlapping with the terminal portion of the flexible printed circuit, the second step of forming the insulating layer 390 by an atomic layer deposition method, and the third step of forming the opening 391 in the region of the insulating layer 390 which overlaps with the terminal portion of the flexible printed circuit FPC. Accordingly, the insulating layer 390 having the opening 391 in the terminal portion of the flexible printed circuit FPC can be formed. Thus, a novel, highly convenient or reliable method for manufacturing a display module can be provided.

### <Modification Example of Method for Manufacturing Display Module>

The method for manufacturing the display module described in this embodiment includes a fourth step in addition to the above steps.

### <<Fourth Step>>

In the fourth step, the resin layer 398 is formed so that the insulating layer 390 is formed in a region interposed between the bonding layer 305 and the resin layer 398 (see FIG. 8C).

This embodiment can be combined with any of the other embodiments and examples in this specification as appropriate.

### Embodiment 5

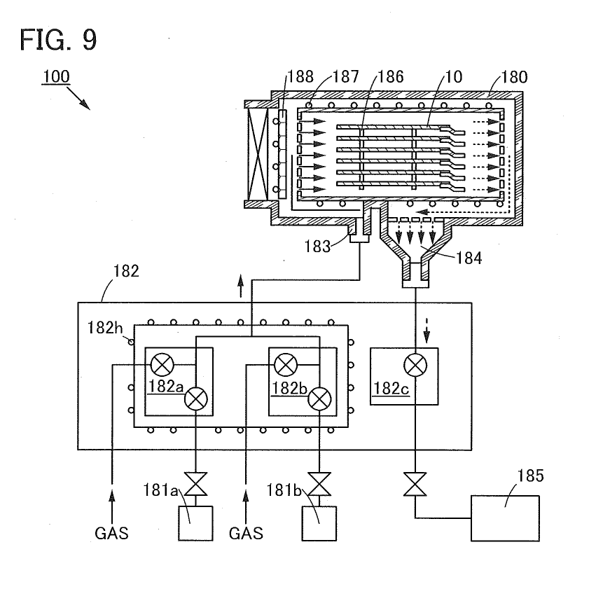

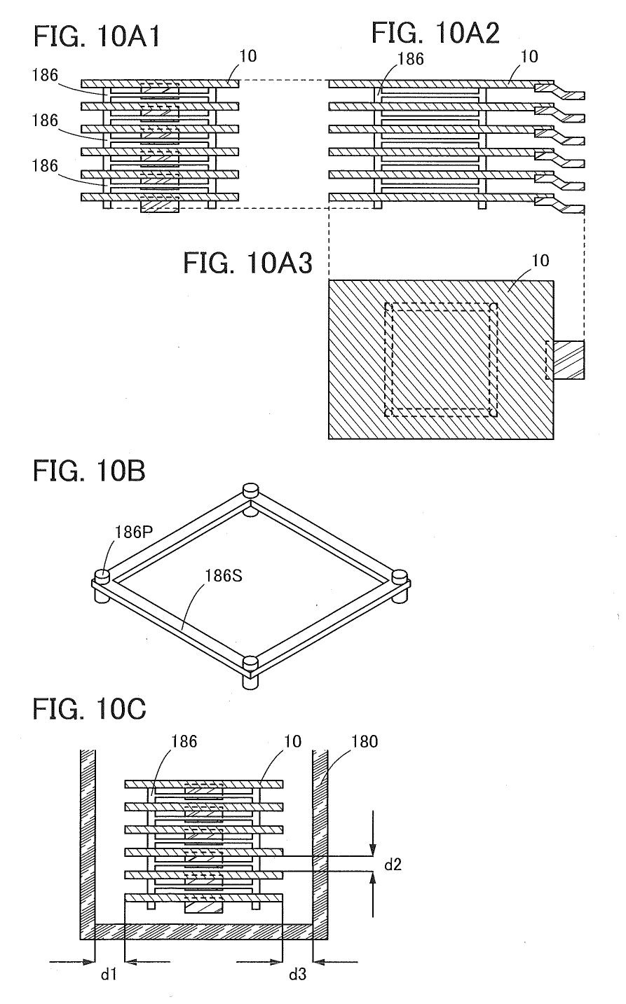

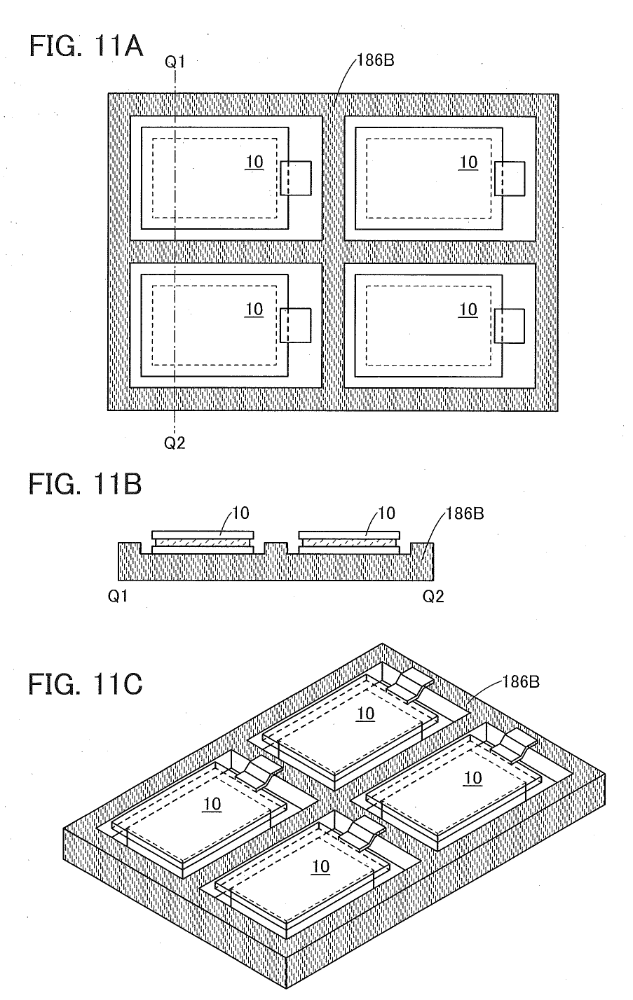

In this embodiment, a deposition apparatus which can be used for manufacturing the display module of one embodiment of the present invention will be described with reference to FIG. 9, FIGS. 10A1, 10A2, 10A3, 10B, and 10C, and FIGS. 11A to 11C.

FIG. 9 is a cross-sectional view illustrating the deposition apparatus 100 which can be used for manufacturing the display module of one embodiment of the present invention.

FIGS. 10A1 to 10A3 illustrate a state in which a process member 10 which can be used for manufacturing the display module of one embodiment of the present invention is supported by a support portion 186.

FIG. 10B is a projection view illustrating the support portions 186 which can be used for manufacturing the display module of one embodiment of the present invention.

FIG. 10C is a side view illustrating a state in which a plurality of process members 10 are prepared in a deposition chamber 180 of the deposition apparatus 100 which can be used for manufacturing the display module of one embodiment of the present invention.

FIGS. 11A to 11C illustrate a state in which the process member 10 which can be used for manufacturing the display module of one embodiment of the present invention is supported by a support portion 186B.

### <Structural Example of Deposition Apparatus 100>

The deposition apparatus 100 described in this embodiment includes the deposition chamber 180 and a control portion 182 connected to the deposition chamber 180.

The control portion 182 includes a control unit (not illustrated) which supplies control signals and flow rate controllers 182a, 182b, and 182c to which the control signals are supplied. For example, high-speed valves can be used as the flow rate controllers. Specifically, flow rates can be precisely controlled by using ALD valves or the like. The control portion 182 also includes a heating mechanism 182h which controls the temperatures of the flow rate controllers and pipes.

The flow rate controller 182a is supplied with a control signal, a first source material, and an inert gas and has a function of supplying the first source material or the inert gas in accordance with the control signal.

The flow rate controller 182b is supplied with a control signal, a second source material, and an inert gas and has a function of supplying the second source material or the inert gas in accordance with the control signal.

The flow rate controller 182c is supplied with a control signal and has a function of connecting to an evacuation unit 185 in accordance with the control signal.

### <<Source Material Supply Portion>>

A source material supply portion 181a has a function of supplying the first source material and is connected to the flow rate controller 182a.

A source material supply portion 181b has a function of supplying the second source material and is connected to the flow rate controller 182b.

A vaporizer, a heating unit, or the like can be used as each of the source material supply portions. Thus, a gaseous source material can be generated from a solid or liquid source material.

Note that the number of source material supply portions is not limited to two and may be three or more.

### <<Source Material>>

Any of a variety of substances can be used as the first source material.

For example, a volatile organometallic compound, a metal alkoxide, or the like can be used as the first source material.

Any of a variety of substances which react with the first source material can be used as the second source material. For example, a substance which contributes to an oxidation reaction, a substance which contributes to a reduction reaction, a substance which contributes to an addition reaction, a substance which contributes to a decomposition reaction, a substance which contributes to a hydrolysis reaction, or the like can be used as the second source material.

Furthermore, a radical or the like can be used. For example, plasma obtained by supplying a source material to a plasma source or the like can be used. Specifically, an oxygen radical, a nitrogen radical, or the like can be used.

A high-frequency power source or a light source can be used as the plasma source. For example, an inductively coupled or capacitively coupled high-frequency power source can be used. Alternatively, an excimer laser, an excimer lamp, a low-pressure mercury lamp, or a synchrotron radiation source can be used as the light source. The second source material combined with the first source material is preferably a source material which reacts with the first source material at a temperature close to room temperature. For example, a source material which reacts at a temperature higher than or equal to room temperature and lower than or equal to 200° C., preferably higher than or equal to 50° C. and lower than or equal to 150° C., is preferable.

### <<Evacuation Unit 185>>

The evacuation unit 185 has an evacuating function and is connected to the flow rate controller 182c. Note that a trap for capturing the source material to be evacuated may be provided between an outlet port 184 and the flow rate controller 182c. The evacuated gas or the like is removed by using a removal unit.

### <<Control Portion 182>>

The control unit supplies the control signals which controls the flow rate controllers, a control signal which controls the heating mechanism, or the like. For example, in a first step, the first source material is supplied to a surface of a process member. Then, in a second step, the second source material which reacts with the first source material is supplied. Accordingly, a reaction product of the first source material and the second source material can be deposited onto a surface of the process member 10.

Note that the amount of the reaction product to be deposited onto the surface of the process member 10 can be controlled by repetition of the first step and the second step.

Note that the amount of the first source material to be supplied to the process member 10 is limited by the maximum possible amount of adsorption on the surface of the process member 10. For example, conditions are selected so that a monomolecular layer of the first source material is formed on the surface of the process member 10, and the formed monomolecular layer of the first source material is reacted with the second source material, whereby a significantly uniform layer containing the reaction product of the first source material and the second source material can be formed.

Accordingly, a variety of materials can be deposited on a surface of the process member 10 even when the surface has a complicated structure. For example, a film having a thickness greater than or equal to 3 nm and less than or equal to 200 nm can be formed on the process member 10.

In the case where, for example, a small hole called a pinhole or the like is formed in the surface of the process member 10, the pinhole can be filled by depositing a material into the pinhole.

The remainder of the first source material or the second source material is evacuated from the deposition chamber 180 with use of the evacuation unit 185. For example, the evacuation may be performed while an inert gas such as argon or nitrogen is introduced.

### <<Deposition Chamber 180>>

The deposition chamber 180 includes an inlet port 183 from which the first source material, the second source material, and the inert gas are supplied and the outlet port 184 from which the first source material, the second source material, and the inert gas are evacuated.

The deposition chamber 180 includes a support portion 186 which has a function of supporting one or a plurality of process members 10, a heating mechanism 187 which has a function of heating the one or plurality of process members, and a door 188 which has a function of opening or closing to load and unload the one or plurality of process members 10.

For example, a resistive heater; an infrared lamp, or the like can be used as the heating mechanism 187.

The heating mechanism 187 has a function of heating up, for example, to 80° C. or higher, 100° C. or higher, or 150° C. or higher.

The heating mechanism 187 heats the one or plurality of process members 10 to a temperature higher than or equal to room temperature and lower than or equal to 200° C., preferably higher than or equal to 50° C. and lower than or equal to 150° C.

The deposition chamber 180 also includes a pressure regulator and a pressure detector.

### <<Support Portion 186>>

The support portion 186 supports the one or plurality of process members 10. Accordingly, an insulating layer, for example, can be formed over the one or plurality of process members 10 in each treatment.

FIG. 9 and FIG. 10A2 illustrate the side surfaces of six process members 10 which are supported by sixth support portions 186, for example. FIG. 10A1 is a side view illustrating the state in FIG. 10A2 viewed from the left side, and FIG. 10A3 is a top view of FIG. 10A2.

The support portion 186 includes a plurality of columnar spacers 186P and a beam portion 186S which connects one spacer and another spacer (see FIG. 10B). Note that the number of columnar spacers 186P included in the support portion 186 is preferably three or more, further preferably four or more and ten or less.

The process member 10 is put on the spacers 186P to be supported by the support portion 186.

On one process member 10 supported by one support portion 186, another support portion 186 can be put to support another process member 10 with the support portion 186. A plurality of process members can be prepared in the deposition chamber 180 by thus alternately stacking the support portion 186 and the process member 10.

Note that the process members 10 are arranged with the support portions 186 which are smaller than the outside shapes of the process members 10 so that the end portions thereof protrude from the support portions 186. Thus, a source material can be uniformly supplied to the end portions and side surfaces of the process members 10 (see FIG. 10C).

The process members 10 are arranged so that the end portions thereof are distant from a wall of the deposition chamber 180. For example, a distance d1 and a distance d3 each between the end portions of the process members 10 and the wall of the deposition chamber 180 is made larger than a distance between one process member 10 and another process member 10. Thus, the source material can be supplied uniformly. Note that the distance d3 can be substantially equal to the distance d1.

FIG. 11A illustrates a top surface of four process members 10 which are supported by a support portion 186B, for example. FIG. 11B is a cross-sectional view taken along the line Q1-Q2 in FIG. 11A, and FIG. 11C is a projection view thereof.

The support portion 186B includes depressed portions in which the process members 10 can be arranged, and the depressed portions are large enough not to be in contact with the side surfaces of the process members 10. Accordingly, for example, an insulating layer can be formed at the same time on the side surfaces of the plurality of process members 10 without being hindered by the support portion 186B.

### <Example of Film>

A film which can be formed with the deposition apparatus 100 described in this embodiment will be described.

For example, a film including an oxide, a nitride, a fluoride, a sulfide, a ternary compound, a metal, or a polymer can be formed.

For example, the film can be formed with a material including aluminum oxide, hafnium oxide, aluminum silicate, hafnium silicate, lanthanum oxide, silicon oxide, strontium titanate, tantalum oxide, titanium oxide, zinc oxide, niobium oxide, zirconium oxide, tin oxide, yttrium oxide, cerium oxide, scandium oxide, erbium oxide, vanadium oxide, indium oxide, or the like.

For example, the film can be formed with a material including aluminum nitride, hafnium nitride, silicon nitride, tantalum nitride, titanium nitride, niobium nitride, molybdenum nitride, zirconium nitride, gallium nitride, or the like.

For example, the film can be formed with a material including copper, platinum, ruthenium, tungsten, iridium, palladium, iron, cobalt, nickel, or the like.

For example, the film can be formed with a material including zinc sulfide, strontium sulfide, calcium sulfide, lead sulfide, calcium fluoride, strontium fluoride, zinc fluoride, or the like.

For example, the film can be formed with a material which includes a nitride containing titanium and aluminum, an oxide containing titanium and aluminum, an oxide containing aluminum and zinc, a sulfide containing manganese and zinc, a sulfide containing cerium and strontium, an oxide containing erbium and aluminum, an oxide containing yttrium and zirconium, or the like.

### <<Film Including Aluminum Oxide>>

For example, a gas obtained by vaporizing a source material including an aluminum precursor compound can be used as the first source material. Specifically, trimethylaluminum (TMA; chemical formula: Al(CH₃)₃), tris(dimethylamide)aluminum, triisobutylaluminum, aluminum tris (2,2,6,6-tetramethyl-3,5-heptanedionate), or the like can be used.

Water vapor (chemical formula: H₂O) can be used as the second source material.

A film including aluminum oxide can be formed from the first source material and the second source material with the deposition apparatus 100.

### <<Film Including Hafnium Oxide>>

For example, a gas obtained by vaporizing a source material including a hafnium precursor compound can be used as the first source material. Specifically, a source material including hafnium amide such as tetrakis(dimethylamide)hafnium (TDMAH; chemical formula: Hf[N(CH₃)₂]₄) or tetrakis(ethylmethylamide)hafnium can be used.

Ozone can be used as the second source material.

### <<Film Including Tungsten>>

For example, a WF₆ gas can be used as the first source material.

A B₂H₆ gas, a SiH₄ gas, or the like can be used as the second source material.

This embodiment can be combined with any of the other embodiments and examples in this specification as appropriate.

### Embodiment 6

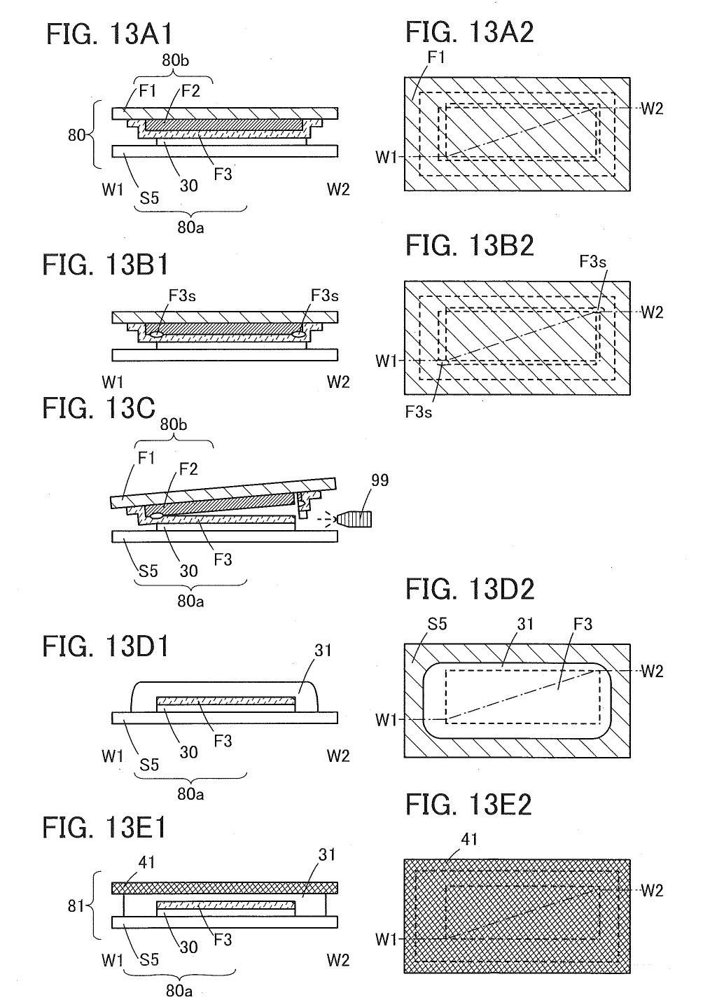

In this embodiment, a method of manufacturing a stack which can be used for manufacturing the display module of one embodiment of the present invention will be described with reference to FIGS. 13A1, 13A2, 13B1, 13B2, 13C, 13D1, 13D2, 13E1, and 13E2.

FIGS. 13A1 to 13E2 are schematic views illustrating a process of manufacturing the stack. Cross-sectional views illustrating structures of a process member and the stack are shown on the left side of FIGS. 13A1 to 13E2, and top views corresponding to the cross-sectional views except FIG. 13C are shown on the right side.

### <Method of Manufacturing Stack>

A method of manufacturing a stack 81 from a process member 80 will be described with reference to FIGS. 13A1 to 13E2.

The process member 80 includes a first substrate F1, a first separation layer F2 on the first substrate F1, a first layer F3 to be separated whose one surface is in contact with the first separation layer F2, a bonding layer 30 whose one surface is in contact with the other surface of the first layer F3 to be separated, and a base S5 in contact with the other surface of the bonding layer 30 (see FIGS. 13A1 and 13A2).

Note that a process member having a structure which will be described in Embodiment 8 in detail can be used as the process member 80, for example.

### <<Formation of Separation Starting Points>>

The process member 80 in which separation starting points F3s are formed in the vicinity of edges of the bonding layer 30 is prepared.

The separation starting point F3s is formed by separating part of the first layer F3 to be separated, from the first substrate F1.

Part of the first layer F3 to be separated can be separated from the separation layer F2 by inserting a sharp tip into the first layer F3 to be separated, from the first substrate F1 side, or by a method using a laser or the like (e.g., a laser ablation method). Thus, the separation starting point F3s can be formed.

### <<First Step>>

The process member 80 in which the separation starting points F3s are formed in the vicinity of the edges of the bonding layer 30 in advance is prepared (see FIGS. 13B1 and 13B2).

### <<Second Step>>

One surface layer 80b of the process member 80 is separated. As a result, a first remaining portion 80a is obtained from the process member 80.

Specifically, from the separation starting point F3s formed in the vicinity of the edge of the bonding layer 30, the first substrate F1, together with the first separation layer F2, is separated from the first layer F3 to be separated (see FIG. 13C). Accordingly, the first remaining portion 80a including the first layer F3 to be separated, the bonding layer 30 whose one surface is in contact with the first layer F3 to be separated, and the base S5 in contact with the other surface of the bonding layer 30 is obtained.

The separation may be performed while the vicinity of the interface between the first separation layer F2 and the first layer F3 to be separated is irradiated with ions to remove static electricity. Specifically, the ions may be generated by an ionizer.

Furthermore, when the first layer F3 to be separated is separated from the first separation layer F2, a liquid is injected into the interface between the first separation layer F2 and the first layer F3 to be separated. Alternatively, a liquid may be ejected and sprayed by a nozzle 99. For example, as the injected liquid or the sprayed liquid, water, a polar solvent, or the like can be used.

By injecting the liquid, an influence of static electricity and the like generated with the separation can be reduced. Alternatively, the separation may be performed while a liquid which dissolves the separation layer is injected.

In particular, in the case where a film including tungsten oxide is used as the first separation layer F2, the first layer F3 to be separated is preferably separated while a liquid containing water is injected or sprayed because a stress applied to the first layer F3 to be separated due to the separation can be reduced.

### <<Third Step>>

A first adhesive layer 31 is formed on the first remaining portion 80a (see FIGS. 13D1 and 13D2), and the first remaining portion 80a is bonded to a first support 41 with the first adhesive layer 31. Accordingly, the stack 81 is obtained from the first remaining portion 80a.

Specifically, the stack 81 including the first support 41, the first adhesive layer 31, the first layer F3 to be separated, the bonding layer 30 whose one surface is in contact with the first layer F3 to be separated, and the base S5 in contact with the other surface of the bonding layer 30 is obtained (see FIGS. 13E1 and 13E2).

To form the bonding layer 30, any of a variety of methods can be used. For example, the bonding layer 30 can be formed with a dispenser, by a screen printing method, or the like. The bonding layer 30 is cured by a method selected in accordance with its material. For example, when a light curable adhesive is used for the bonding layer 30, light including light of a predetermined wavelength is emitted.

This embodiment can be combined with any of the other embodiments and examples in this specification as appropriate.

### Embodiment 7

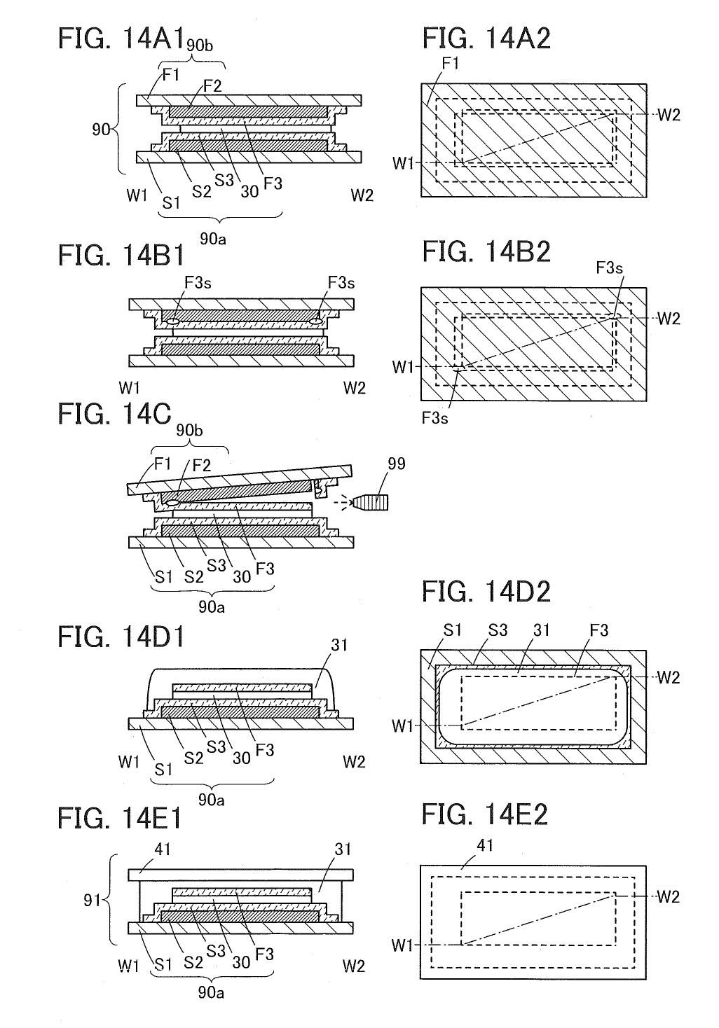

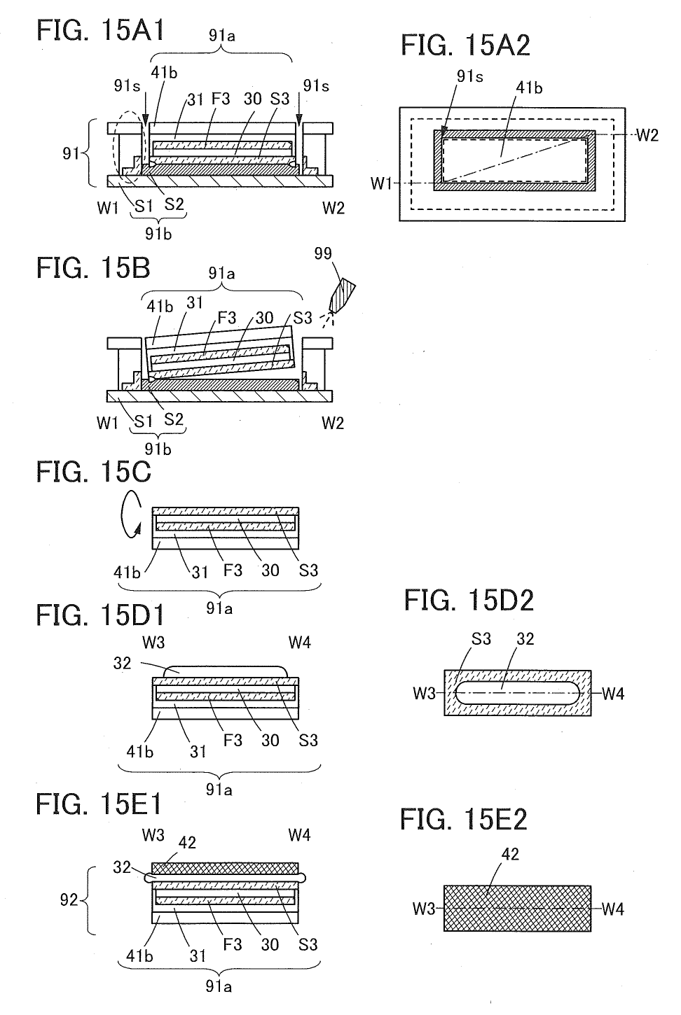

In this embodiment, a method of manufacturing a stack which can be used for manufacturing the display module of one embodiment of the present invention will be described with reference to FIGS. 14A1, 14A2, 14B1, 14B2, 14C, 14D1, 14D2, 14E1, and 14E2, and FIGS. 15A1, 15A2, 15B, 15C, 15D1, 15D2, 15E1, and 15E2.

FIGS. 14A1 to 14E2 and FIGS. 15A1 to 15E2 are schematic views illustrating a process of manufacturing the stack. Cross-sectional views illustrating structures of a process member and the stack are shown on the left side of FIGS. 14A1 to 14E2 and FIGS. 15A1 to 15E2, and top views corresponding to the cross-sectional views except FIG. 14C and FIGS. 15B and 15C are shown on the right side.

### <Method of Manufacturing Stack>

A method of manufacturing a stack 92 from a process member 90 will be described with reference to FIGS. 14A1 to 14E2 and FIGS. 15A1 to 15E2.

The process member 90 is different from the process member 80 in that the other surface of the bonding layer 30 is in contact with one surface of a second layer S3 to be separated.

Specifically, the difference is that a stack including a second substrate S1, a second separation layer S2 over the second substrate S1, and the second layer S3 to be separated whose other surface is in contact with the second separation layer S2 is provided instead of the base S5, and that one surface of the second layer S3 to be separated is in contact with the other surface of the bonding layer 30, in the process member 90.

In the process member 90, the first substrate F1, the first separation layer F2, the first layer F3 to be separated whose one surface is in contact with the first separation layer F2, the bonding layer 30 whose one surface is in contact with the other surface of the first layer F3 to be separated, the second layer S3 to be separated whose one surface is in contact with the other surface of the bonding layer 30, the second separation layer S2 whose one surface is in contact with the other surface of the second layer S3 to be separated, and the second substrate S1 are placed in this order (see FIGS. 14A1 and 14A2).

Note that a process member having a structure which will be described in Embodiment 8 in detail can be used as the process member 90, for example.

### <<First Step>>

The process member 90 in which the separation starting points F3s are formed in the vicinity of the edges of the bonding layer 30 is prepared (see FIGS. 14B1 and 14B2).

The separation starting point F3s is formed by separating part of the first layer F3 to be separated, from the first substrate F1.

For example, part of the first layer F3 to be separated can be separated from the separation layer F2 by inserting a sharp tip into the first layer F3 to be separated, from the first substrate F1 side, or by a method using a laser or the like (e.g., a laser ablation method). Thus, the separation starting point F3s can be formed.

### <<Second Step>>

One surface layer 90b of the process member 90 is separated. As a result, a first remaining portion 90a is obtained from the process member 90.

Specifically, from the separation starting point F3s formed in the vicinity of the edge of the bonding layer 30, the first substrate F1, together with the first separation layer F2, is separated from the first layer F3 to be separated (see FIG. 14C). Accordingly, the first remaining portion 90a in which the first layer F3 to be separated, the bonding layer 30 whose one surface is in contact with the first layer F3 to be separated, the second layer S3 to be separated whose one surface is in contact with the other surface of the bonding layer 30, the second separation layer S2 whose one surface is in contact with the other surface of the second layer S3 to be separated, and the second substrate S1 are placed in this order is obtained.

Note that the separation may be performed while the vicinity of the interface between the second separation layer S2 and the second layer S3 to be separated is irradiated with ions to remove static electricity. Specifically, the ions may be generated by an ionizer.

Furthermore, when the second layer S3 to be separated is separated from the second separation layer S2, a liquid is injected into the interface between the second separation layer S2 and the second layer S3 to be separated. Alternatively, a liquid may be ejected and sprayed by a nozzle 99. For example, as the liquid to be injected or the liquid to be sprayed, water, a polar solvent, or the like can be used.

By injecting the liquid, an influence of static electricity and the like generated with the separation can be reduced. Alternatively, the separation may be performed while a liquid which dissolves the separation layer is injected.

In particular, in the case where a film including tungsten oxide is used as the second separation layer S2, the second layer S3 to be separated is preferably separated while a liquid containing water is injected or sprayed because a stress applied to the second layer S3 to be separated due to the separation can be reduced.

### <<Third Step>>

A first adhesive layer 31 is formed on the first remaining portion 90a (see FIGS. 14D1 and 14D2), and the first remaining portion 90a is bonded to a first support 41 with the first adhesive layer 31. Accordingly, a stack 91 is obtained from the first remaining portion 90a.

Specifically, the stack 91 in which the first support 41, the first adhesive layer 31, the first layer F3 to be separated, the bonding layer 30 whose one surface is in contact with the first layer F3 to be separated, the second layer S3 to be separated whose one surface is in contact with the other surface of the bonding layer 30, the second separation layer S2 whose one surface is in contact with the other surface of the second layer S3 to be separated, and the second substrate Si are placed in this order is obtained (see FIGS. 14E1 and 14E2).

### <<Fourth Step>>

Part of the second layer S3 to be separated in the vicinity of the edge of the first adhesive layer 31 of the stack 91 is separated from the second substrate S1 to form a separation starting point 91s.

For example, the first support 41 and the first adhesive layer 31 are cut from the first support 41 side, and part of the second layer S3 to be separated is separated from the second substrate S1 along an edge of the first adhesive layer 31 which is newly formed.

Specifically, the first adhesive layer 31 and the first support 41 in a region which is over the second separation layer S2 and in which the second layer S3 to be separated is provided are cut with a blade or the like including a sharp tip, and along a newly formed edge of the first adhesive layer 31, the second layer S3 to be separated is partly separated from the second substrate S1 (see FIGS. 15A1 and 15A2).

Consequently, the separation starting points 91s are formed in the vicinity of newly formed edges of the first support 41b and the first adhesive layer 31.

### <<Fifth Step>>

A second remaining portion 91a is separated from the stack 91. As a result, the second remaining portion 91a is obtained from the stack 91 (see FIG. 15C).

Specifically, from the separation starting point 91s formed in the vicinity of the edge of the first adhesive layer 31, the second substrate S1, together with the second separation layer S2, is separated from the second layer S3 to be separated. Accordingly, the second remaining portion 91a in which the first support 41b, the first adhesive layer 31, the first layer F3 to be separated, the bonding layer 30 whose one surface is in contact with the first layer F3 to be separated, and the second layer S3 to be separated whose one surface is in contact with the other surface of the bonding layer 30 are placed in this order is obtained.

Note that the separation may be performed while the vicinity of the interface between the second separation layer S2 and the second layer S3 to be separated is irradiated with ions to remove static electricity. Specifically, the ions may be generated by an ionizer.

Furthermore, when the second layer S3 to be separated is separated from the second separation layer S2, a liquid is injected into the interface between the second separation layer S2 and the second layer S3 to be separated. Alternatively, a liquid may be ejected and sprayed by the nozzle 99. For example, as the liquid to be injected or the liquid to be sprayed, water, a polar solvent, or the like can be used.

By injecting the liquid, an influence of static electricity and the like generated with the separation can be reduced. Alternatively, the separation may be performed while a liquid which dissolves the separation layer is injected.

In particular, in the case where a film including tungsten oxide is used as the second separation layer S2, the second layer S3 to be separated is preferably separated while a liquid containing water is injected or sprayed because a stress applied to the second layer S3 to be separated due to the separation can be reduced.

### <<Sixth Step>>

A second adhesive layer 32 is formed on the second remaining portion 91a (see FIGS. 15D1 and 15D2).

The second remaining portion 91a is bonded to a second support 42 with the second adhesive layer 32. Consequently, the stack 92 is obtained from the second remaining portion 91a (see FIGS. 15E1 and 15E2).

Specifically, the stack 92 in which first support 41b, the first adhesive layer 31, the first layer F3 to be separated, the bonding layer 30 whose one surface is in contact with the first layer F3 to be separated, the second layer S3 to be separated whose one surface is in contact with the other surface of the bonding layer 30, the second adhesive layer 32, and the second support 42 are placed in this order is obtained.

### <Method of Manufacturing Stack Including Opening in Support>

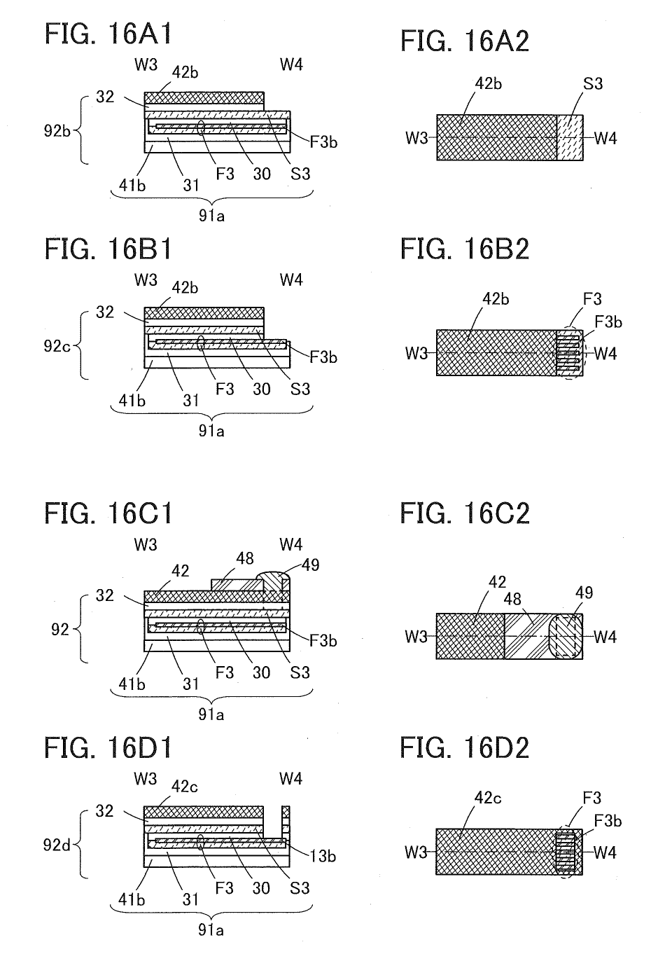

A method of manufacturing a stack including an opening in a support will be described with reference to FIGS. 16A1, 16A2, 16B1, 16B2, 16C1, 16C2, 16D1, and 16D2.

FIGS. 16A1 to 16D2 illustrate the method of manufacturing a stack including an opening which exposes part of a layer to be separated in a support. Cross-sectional views illustrating structures of the stack are shown on the left side of FIGS. 16A1 to 16D2, and top views corresponding to the cross-sectional views are shown on the right side.

FIGS. 16A1 to 16B2 illustrate a method of manufacturing a stack 92c including an opening by using a second support 42b which is smaller than the first support 41b.

FIGS. 16C1 to 16D2 illustrate a method of manufacturing a stack 92d including an opening formed in the second support 42.

### <<Example 1 of Method of Manufacturing Stack Including Opening in Support>>

This method of manufacturing a stack has the same steps as the above except that the second support 42b which is smaller than the first support 41b is used instead of the second support 42 in the sixth step. By this method, a stack in which part of the second layer S3 to be separated is exposed can be manufactured (see FIGS. 16A1 and 16A2).

As the second adhesive layer 32, a liquid adhesive can be used. Alternatively, an adhesive whose fluidity is inhibited and which is formed in a single wafer shape in advance (also referred to as a sheet-like adhesive) can be used. By using the sheet-like adhesive, the amount of part of the second adhesive layer 32 which extends beyond the second support 42b can be small. In addition, the second adhesive layer 32 can have a uniform thickness easily.

Part of the second layer S3 to be separated, which is exposed, may be cut off, such that the first layer F3 to be separated is exposed (see FIGS. 16B1 and 16B2).

Specifically, with a blade or the like which has a sharp tip, a slit is formed in the exposed second layer S3 to be separated. Then, for example, an adhesive tape or the like is attached to part of the exposed second layer S3 to be separated to concentrate stress near the slit, and the part of the exposed second layer S3 to be separated is separated together with the attached tape or the like, whereby the part of the second layer S3 to be separated can be selectively removed.

Moreover, a layer which can suppress the bonding power of the bonding layer 30 to the first layer F3 to be separated may be selectively formed on part of the first layer F3 to be separated. For example, a material which is not easily bonded to the bonding layer 30 may be selectively formed. Specifically, an organic material may be deposited into an island shape. Thus, part of the bonding layer 30 can be selectively removed together with the second layer S3 to be separated easily. As a result, the first layer F3 to be separated can be exposed.

Note that for example, in the case where the first layer F3 to be separated includes a functional layer and a conductive layer F3b electrically connected to the functional layer, the conductive layer F3b can be exposed in an opening of the second stack 92c. Thus, the conductive layer F3b exposed in the opening can be used as a terminal supplied with a signal.

As a result, the conductive layer F3b part of which is exposed in the opening can be used as a terminal which can extract a signal supplied though the functional layer, or can be used as a terminal to which a signal supplied to the functional layer can be supplied by an external device.

### <<Example 2 of Method of Manufacturing Stack Including Opening in Support>>

A mask 48 including an opening formed to overlap with an opening formed in the second support 42 is formed on the stack 92. Next, a solvent 49 is dropped into the opening of the mask 48. Thus, with the solvent 49, the second support 42 exposed in the opening of the mask 48 can be swelled or dissolved (see FIGS. 16C1 and 16C2).

After the extra solvent 49 is removed, stress is applied by, for example, rubbing the second support 42 exposed in the opening of the mask 48. Thus, the second support 42 or the like in a region overlapping with the opening of the mask 48 can be removed.

Moreover, with a solvent with which the, bonding layer 30 is swelled or dissolved, the first layer F3 to be separated can be exposed (see FIGS. 16D1 and 16D2).

This embodiment can be combined with any of the other embodiments and examples in this specification as appropriate.

### Embodiment 8

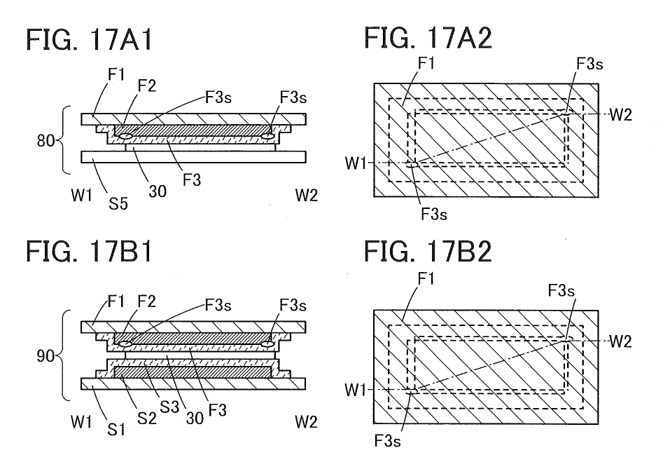

In this embodiment, a structure of a process member which can be processed into the display module of one embodiment of the present invention will be described with reference to FIGS. 17A1, 17A2, 17B1, and 17B2.

FIGS. 17A1 to 17B2 are schematic views illustrating a structure of a process member which can be processed into the stack.

FIG. 17A1 is a cross-sectional view illustrating a structure of the process member 80 which can be processed into the stack, and FIG. 17A2 is a top view corresponding to the cross-sectional view.

FIG. 17B1 is a cross-sectional view illustrating a structure of the process member 90 which can be processed into the stack, and FIG. 17B2 is a top view corresponding to the cross-sectional view.

### <Structural Example 1 of Process Member>

The process member 80 includes the first substrate F1, the first separation layer F2 on the first substrate F1, the first layer F3 to be separated whose one surface is in contact with the first separation layer F2, the bonding layer 30 whose one surface is in contact with the other surface of the first layer F3 to be separated, and the base S5 in contact with the other surface of the bonding layer 30 (see FIGS. 17A1 and 17A2).

Note that the separation starting points F3s may be formed in the vicinity of the edges of the bonding layer 30.

### <<First Substrate>>

There is no particular limitation on the first substrate F1 as long as it has heat resistance high enough to withstand a manufacturing process and a thickness and a size that allow the first substrate F1 to be placed in a manufacturing apparatus.

For the first substrate F1, an organic material, an inorganic material, a composite material of an organic material and an inorganic material, or the like can be used.

For example, an inorganic material such as glass, ceramic, or metal can be used for the first substrate F1.

Specifically, non-alkali glass, soda-lime glass, potash glass, crystal glass, or the like can be used for the first substrate F1.

Specifically, a metal oxide film, a metal nitride film, a metal oxynitride film, or the like can be used for the first substrate F1. For example, a silicon oxide film, a silicon nitride film, a silicon oxynitride film, an alumina film, or the like can be used for the first substrate F1.

Specifically, SUS, aluminum, or the like can be used for the first substrate F1.

For example, an organic material such as a resin, a resin film, or a plastic can be used for the first substrate F1.

Specifically, a resin film or a resin plate of polyester, polyolefin, polyamide, polyimide, polycarbonate, an acrylic resin, or the like can be used for the first substrate F1.

For example, a composite material such as a resin film to which a metal plate, a thin glass plate, or a film of an inorganic material is attached can be used as the first substrate F1.

For example, a composite material formed by dispersing a fibrous or particulate metal, glass, an inorganic material, or the like into a resin film can be used as the first substrate F1.

For example, a composite material formed by dispersing a fibrous or particulate resin, an organic material, or the like into an inorganic material can be used as the first substrate F1.

For the first substrate F1, a single-layer material or a stacked-layer material in which a plurality of layers are stacked can be used. For example, a stacked-layer material in which a base, an insulating layer which prevents diffusion of impurities contained in the base, and the like are stacked can be used for the first substrate F1.

Specifically, a stacked-layer material in which glass and one or a plurality of films which prevents diffusion of impurities contained in the glass and that are selected from a silicon oxide film, a silicon nitride film, a silicon oxynitride film, and the like are stacked can be used for the first substrate F1.

Alternatively, a stacked-layer material in which a resin, a film which prevents diffusion of impurities contained in the resin, such as a silicon oxide film, a silicon nitride film, or a silicon oxynitride film, and the like are stacked can be used for the first substrate F1.

### <<First Separation Layer>>

The first separation layer F2 is provided between the first substrate F1 and the first layer F3 to be separated. In the vicinity of the first separation layer F2, a boundary where the first layer F3 to be separated can be separated from the first substrate F1 is formed. There is no particular limitation on the first separation layer F2 as long as it has heat resistance high enough to withstand the manufacturing process of the first layer F3 to be separated formed thereon.

For the first separation layer F2, for example, an inorganic material, an organic resin, or the like can be used.

Specifically, an inorganic material such as a metal containing an element selected from tungsten, molybdenum, titanium, tantalum, niobium, nickel, cobalt, zirconium, zinc, ruthenium, rhodium, palladium, osmium, iridium, and silicon; an alloy including any of the elements; or a compound including any of the elements can be used for the first separation layer F2.

Specifically, an organic material such as polyimide, polyester, polyolefin, polyamide, polycarbonate, or an acrylic resin can be used.

For example, a single-layer material or a stacked-layer material in which a plurality of layers are stacked can be used for the first separation layer F2.

Specifically, a material in which a layer containing tungsten and a layer containing an oxide of tungsten are stacked can be used for the first separation layer F2.

The layer containing an oxide of tungsten can be formed by a method in which another layer is stacked on a layer containing tungsten. Specifically, the layer containing an oxide of tungsten may be formed by a method in which silicon oxide, silicon oxynitride, or the like is stacked on a layer containing tungsten.

The layer containing an oxide of tungsten may be fouled by subjecting a surface of a layer containing tungsten to thermal oxidation treatment, oxygen plasma treatment, nitrous oxide (N₂O) plasma treatment, treatment with a solution with high oxidizing power (e.g., ozone water), or the like.

Specifically, a layer containing polyimide can be used as the first separation layer F2. The layer containing polyimide has heat resistance high enough to withstand the various manufacturing steps required to form the first layer F3 to be separated.

For example, the layer containing polyimide has heat resistance of 200° C. or higher, preferably 250° C. or higher, further preferably 300° C. or higher, and still further preferably 350° C. or higher.

By heating a film containing a monomer formed on the first substrate F1, a film containing polyimide obtained by condensation of the monomer can be obtained. Such a film can be used as the layer containing polyimide.

### <<First Layer to be Separated>>

There is no particular limitation on the first layer F3 to be separated as long as it can be separated from the first substrate F1 and has heat resistance high enough to withstand the manufacturing process.

The boundary where the first layer F3 to be separated can be separated from the first substrate F1 may be formed between the first layer F3 to be separated and the first separation layer F2 or may be formed between the first separation layer F2 and the first substrate F1.

In the case where the boundary is formed between the first layer F3 to be separated and the first separation layer F2, the first separation layer F2 is not included in the stack. In the case where the boundary is formed between the first separation layer F2 and the first substrate F1, the first separation layer F2 is included in the stack.

An inorganic material, an organic material, a single-layer material, a stacked-layer material in which a plurality of layers are stacked, or the like can be used for the first layer F3 to be separated.

For example, an inorganic material such as a metal oxide film, a metal nitride film, or a metal oxynitride film can be used for the first layer F3 to be separated.

Specifically, a silicon oxide film, a silicon nitride film, a silicon oxynitride film, an alumina film, or the like can be used for the first layer F3 to be separated.

Specifically, a resin, a resin film, plastic, or the like can be used for the first layer F3 to be separated.

Specifically, a polyimide film or the like can be used for the first layer F3 to be separated.

For example, a material having a structure in which a functional layer which has a region overlapping with the first separation layer F2 and an insulating layer which is provided between the first separation layer F2 and the functional layer and can prevent the diffusion of impurities which impair the function of the functional layer are stacked can be used.

Specifically, a 0.7-mm-thick glass plate is used as the first substrate F1, and a stacked-layer material in which a 200-nm-thick silicon oxynitride film and a 30-nm-thick tungsten film are stacked in this order from the first substrate F1 side is used for the first separation layer F2. In addition, a film including a stacked-layer material in which a 600-nm-thick silicon oxynitride film and a 200-nm-thick silicon nitride film are stacked in this order from the first separation layer F2 side can be used as the first layer F3 to be separated. Note that a silicon oxynitride film refers to a film which includes more oxygen than nitrogen, and a silicon nitride oxide film refers to a film which includes more nitrogen than oxygen.

Specifically, instead of the above first layer F3 to be separated, a film including a stacked-layer material of a 600-nm-thick silicon oxynitride film, a 200-nm-thick silicon nitride film, a 200-nm-thick silicon oxynitride film, a 140-nm-thick silicon nitride oxide film, and a 100-nm-thick silicon oxynitride film stacked in this order from the first separation layer F2 side can be used as the first layer F3 to be separated.

Specifically, a stacked-layer material in which a polyimide film, a layer containing silicon oxide, silicon nitride, or the like, and the functional layer are stacked in this order from the first separation layer F2 side can be used.

### <<Functional Layer>>

The functional layer is included in the first layer F3 to be separated.

For example, a functional circuit, a functional element, an optical element, a functional film, or a layer including a plurality of elements selected from these can be used as the functional layer.

Specifically, a display element which can be used for a display device, a pixel circuit driving the display element, a driver circuit driving the pixel circuit, a color filter, a moisture-proof film, and the like, and a layer including two or more selected from these can be given.

### <<Bonding Layer>>

There is no particular limitation on the bonding layer 30 as long as it bonds the first layer F3 to be separated and the base S5 to each other.

For the bonding layer 30, an inorganic material, an organic material, a composite material of an inorganic material and an organic material, or the like can be used.

For example, a glass layer with a melting point of 400° C. or lower, preferably 300° C. or lower, an adhesive, or the like can be used.

For example, an organic material such as a light curable adhesive, a reactive curable adhesive, a thermosetting adhesive, and/or an anaerobic adhesive can be used for the bonding layer 30.

Specifically, an adhesive containing an epoxy resin, an acrylic resin, a silicone resin, a phenol resin, a polyimide resin, an imide resin, a polyvinyl chloride (PVC) resin, a polyvinyl butyral (PVB) resin, and an ethylene vinyl acetate (EVA) resin, or the like can be used.

### <<Base>>

There is no particular limitation on the base S5 as long as it has heat resistance high enough to withstand a manufacturing process and a thickness and a size which allow the base S5 to be placed in a manufacturing apparatus.

A material that can be used for the base S5 can be the same as that of the first substrate F1, for example.

### <<Separation Starting Point>>

In the process member 80, the separation starting point F3s may be formed in the vicinity of the edges of the bonding layer 30.

The separation starting point F3s is formed by separating part of the first layer F3 to be separated, from the first substrate F1.

Part of the first layer F3 to be separated can be separated from the separation layer F2 by inserting a sharp tip into the first layer F3 to be separated, from the first substrate F1 side, or by a method using a laser or the like (e.g., a laser ablation method). Thus, the separation starting point F3s can be formed.

### <Structural Example 2 of Process Member>

A structure of the process member which can be the stack and is different from the above will be described with reference to FIGS. 17B1 and 17B2.

The process member 90 is different from the process member 80 in that the other surface of the bonding layer 30 is in contact with one surface of the second layer S3 to be separated instead of the base S5.

Specifically, the process member 90 includes the first substrate F1 on which the first separation layer F2 and the first layer F3 to be separated whose one surface is in contact with the first separation layer F2 are formed, the second substrate S1 on which the second separation layer S2 and the second layer S3 to be separated whose other surface is in contact with the second separation layer S2 are formed, and the bonding layer 30 whose one surface is in contact with the other surface of the first layer F3 to be separated and whose other surface is in contact with the one surface of the second layer S3 to be separated (see FIGS. 17B1 and 17B2).

### <<Second Substrate>>

As the second substrate S1, a substrate similar to the first substrate F1 can be used. Note that the second substrate S1 need not necessarily have the same structure as the first substrate F1.

### <<Second Separation Layer>>

For the second separation layer S2, a structure similar to that of the first separation layer F2 can be used. For the second separation layer S2, a structure different from that of the first separation layer F2 can also be used.

### <<Second Layer to be Separated>>

As the second layer S3 to be separated, a structure similar to that of the first layer F3 to be separated can be used. For the second layer S3 to be separated, a structure different from that of the first layer F3 to be separated can also be used.

Specifically, a structure may be employed in which the first layer F3 to be separated includes a functional circuit and the second layer S3 to be separated includes a functional layer which prevents the diffusion of impurities into the functional circuit.

Specifically, a structure may be employed in which the first layer F3 to be separated includes a light-emitting element which emits light to the second layer S3 to be separated, a pixel circuit driving the light-emitting element, and a driver circuit driving the pixel circuit, and the second layer S3 to be separated includes a color filter which transmits part of light emitted from the light-emitting element and a moisture-proof film which prevents the diffusion of impurities into the light-emitting element. Note that the process member with such a structure can be used for a stack which can be used as a flexible display device.

This embodiment can be combined with any of the other embodiments and examples in this specification as appropriate.

### Embodiment 9

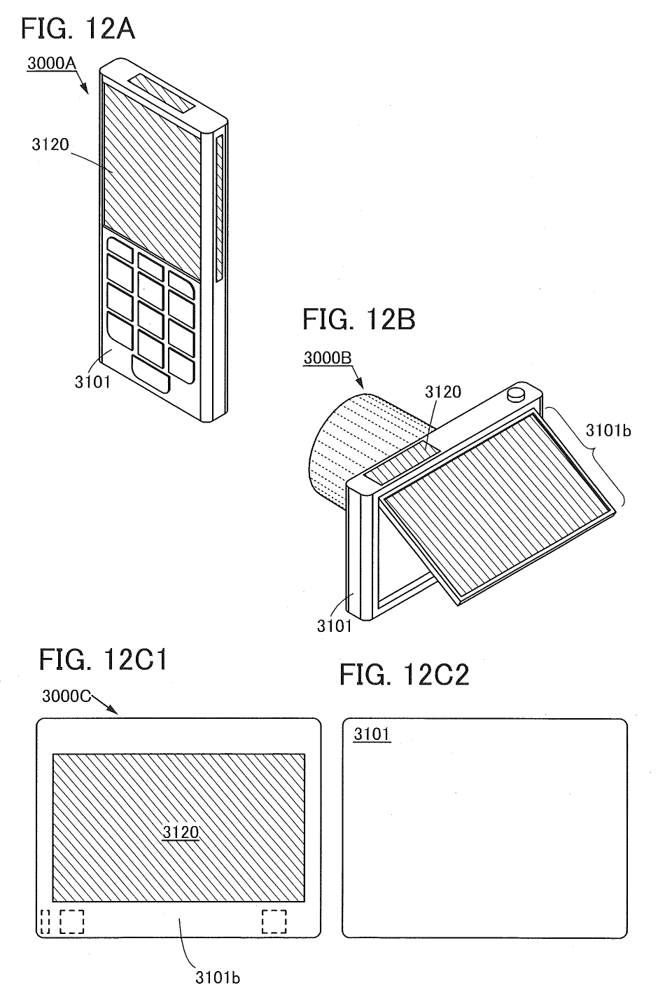

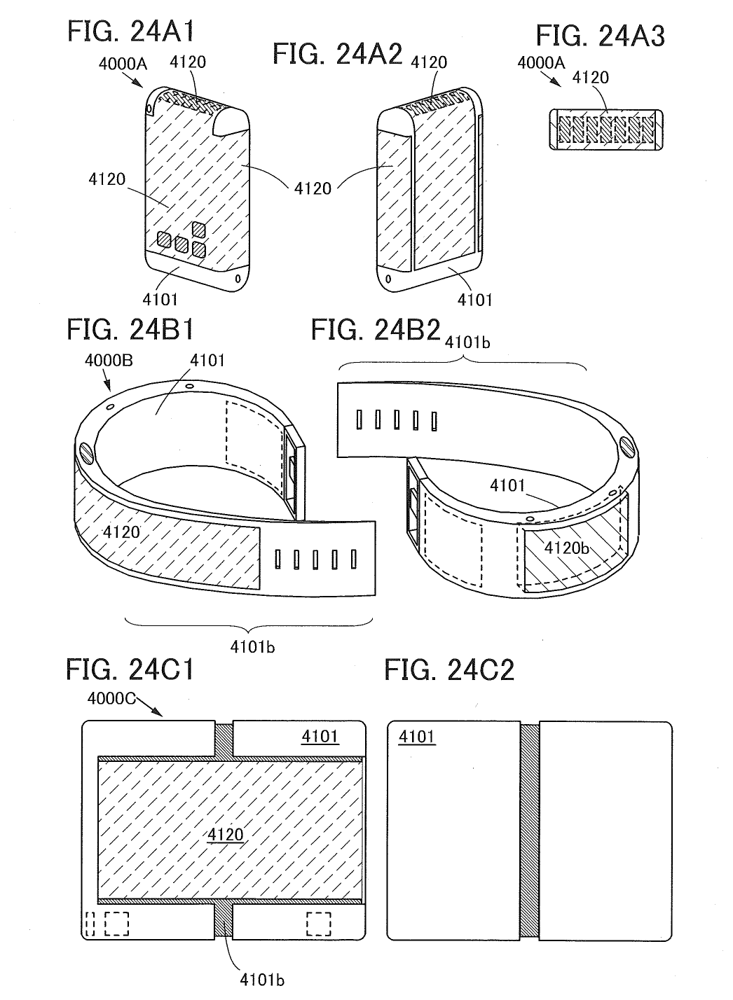

In this embodiment, a structure of a data processor of one embodiment of the present invention will be described with reference to FIGS. 12A, 12B, 12C1, and 12C2 and FIGS. 24A1, 24A2, 24A3, 24B1, 24B2, 24C1, and 24C2.

FIGS. 12A1 to 12C2 are projection views of a data processor of one embodiment of the present invention.

FIG. 12A is a projection view of a data processor 3000A of one embodiment of the present invention.

FIG. 12B is a projection view of a data processor 3000B of one embodiment of the present invention.

FIGS. 12C1 and 12C2 are a top view and a bottom view of a data processor 3000C of one embodiment of the present invention.

FIGS. 24A1 to 24C2 are projection views of a data processor of one embodiment of the present invention.

FIG. 24A1 to 24A3 are each a projection view of a data processor 4000A of one embodiment of the present invention.

FIGS. 24B1 and 24B2 are each a projection view of a data processor 4000B of one embodiment of the present invention.

FIGS. 24C1 and 24C2 are a top view and a bottom view of a data processor 4000C of one embodiment of the present invention.

### <<Data Processor A>>

The data processor 3000A includes an input/output portion 3120 and a housing 3101 which supports the input/output portion 3120 (see FIG. 12A).

The input/output portion 3120 includes a display module of one embodiment of the present invention. For example, the display module described in Embodiment 3 can be used for the input/output portion 3120.

The data processor 3000A further includes an arithmetic unit, a memory unit which stores a program to be executed by the arithmetic unit, and a power source such as a battery which supplies power for driving the arithmetic unit.

Note that the housing 3101 houses the arithmetic unit, the memory unit, the battery, and the like.

The data processor 3000A can display display information on its side surface and/or top surface.

A user of the data processor 3000A can supply operation instructions by using a finger in contact with the side surface and/or the top surface.

### <<Data Processor B>>

The data processor 3000B includes the housing 3101 and a housing 3101b connected to the housing 3101 with a hinge (see FIG. 12B).

The housing 3101 supports the input/output portion 3120.

The housing 3101b supports an input/output portion 3120b.

The input/output portion 3120 or the input/output portion 3120b includes a display module of one embodiment of the present invention. For example, the display module described in Embodiment 3 can be used for the input/output portion 3120.

The data processor 3000B further includes an arithmetic unit, a memory unit which stores a program to be executed by the arithmetic unit, and a power source such as a battery which supplies power for driving the arithmetic unit.

Note that the housing 3101 houses the arithmetic unit, the memory unit, the battery, and the like.

The data processor 3000B can display information on the input/output portion 3120 or the input/output portion 3120b.

A user of the data processor 3000B can supply operation instructions by using a finger in contact with the input/output portion 3120 or the input/output portion 3120b.

### <<Data Processor C>>

The data processor 3000C includes the input/output portion 3120 and the housings 3101 and 3101b which supports the input/output portion 3120 (see FIGS. 12C1 and 12C2).

The input/output portion 3120 includes a display module of one embodiment of the present invention. For example, the display module described in Embodiment 3 can be used for the input/output portion 3120.

The data processor 3000C further includes an arithmetic unit, a memory unit which stores a program to be executed by the arithmetic unit, and a power source such as a battery which supplies power for driving the arithmetic unit.

Note that the housing 3101 houses the arithmetic unit, the memory unit, the battery, and the like.

### <<Data Processor D>>

The data processor 4000A includes an input/output portion 4120 and a housing 4101 which supports the input/output portion 4120 (see FIGS. 24A1 to 24A3).

The input/output portion 4120 includes a display module of one embodiment of the present invention. For example, the display module described in Embodiment 3 can be used for the input/output portion 4120.

The data processor 4000A further includes an arithmetic unit, a memory unit which stores a program to be executed by the arithmetic unit, and a power source such as a battery which supplies power for driving the arithmetic unit.

Note that the housing 4101 houses the arithmetic unit, the memory unit, the battery, and the like.

The data processor 4000A can display display information on its side surface and/or top surface.

A user of the data processor 4000A can supply operation instructions by using a finger in contact with the side surface and/or the top surface.

### <<Data Processor E>>

The data processor 4000B includes the housing 4101 and a housing 4101b connected to the housing 4101 with a hinge (see FIGS. 24B1 and 24B2).

The housing 4101 supports the input/output portion 4120.

The housing 4101b supports an input/output portion 4120b.

The input/output portion 4120 or the input/output portion 4120b includes a display module of one embodiment of the present invention. For example, the display module described in Embodiment 3 can be used for the input/output portion 4120.

The data processor 4000B further includes an arithmetic unit, a memory unit which stores a program to be executed by the arithmetic unit, and a power source such as a battery which supplies power for driving the arithmetic unit.

Note that the housing 4101 houses the arithmetic unit, the memory unit, the battery, and the like.

The data processor 4000B can display information on the input/output portion 4120 or the input/output portion 4120b.

A user of the data processor 4000B can supply operation instructions by using a finger in contact with the input/output portion 4120 or the input/output portion 4120b.

### <<Data Processor F>>

The data processor 4000C includes the input/output portion 4120 and the housing 4101 which supports the input/output portion 4120 (see FIGS. 24C1 and 24C2).

The input/output portion 4120 includes a display module of one embodiment of the present invention. For example, the display module described in Embodiment 3 can be used for the input/output portion 4120.

The data processor 4000C further includes an arithmetic unit, a memory unit which stores a program to be executed by the arithmetic unit, and a power source such as a battery which supplies power for driving the arithmetic unit.

Note that the housing 4101 houses the arithmetic unit, the memory unit, the battery, and the like.

This embodiment can be combined with any of the other embodiments and examples in this specification as appropriate.

### Example 1

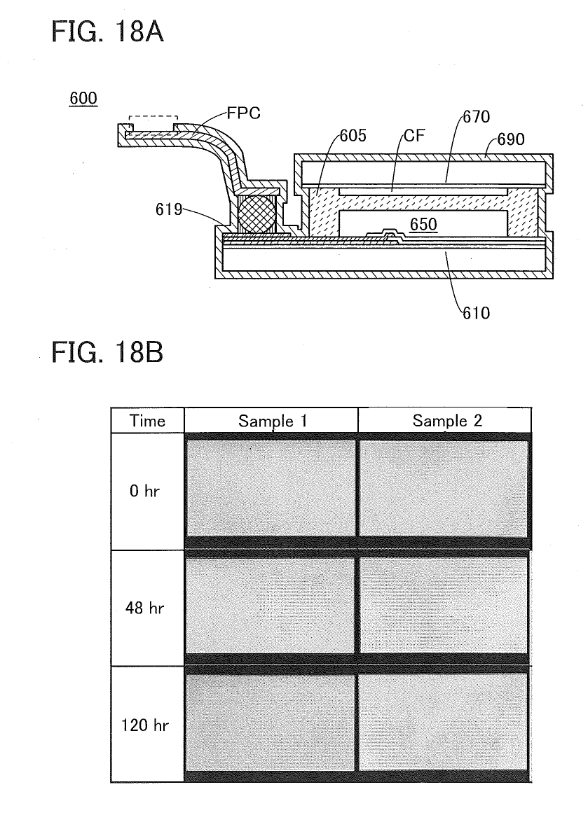

In this example, a fabricated display module of one embodiment of the present invention will be described with reference to FIGS. 18A and 18B.

FIG. 18A illustrates a structure of a fabricated display module, and FIG. 18B shows photographs of the display module. FIG. 18A is a cross-sectional view illustrating the structure, and FIG. 18B shows the photographs of the display module in the display state.

### <<Structure>>

The fabricated display module 600 includes a terminal 619, a first base 610 which supports the terminal 619, a second base 670 which has a region overlapping with the first base 610, a bonding layer 605 which has a function of bonding the first base 610 and the second base 670, a display element 650 which is provided between the first base 610 and the second base 670 and is electrically connected to the terminal 619, a flexible printed circuit FPC electrically connected to the terminal 619, and an insulating layer 690 in contact with the first base 610, the second base 670, the bonding layer 605, and the flexible printed circuit FPC (see FIG. 18A).

Note that 0.7-mm-thick non-alkali glass plates were used for the first base 610 and the second base 670.

A white-light-emitting organic EL element was used for the display element 650.

The display module includes a coloring layer CF on a light-emitting side of the organic EL element, and the coloring layer CF has a region overlapping with the organic EL element.

A display portion includes a display region with a diagonal of 3.4 inches, a driver circuit SD, and a driver circuit GD. The display region includes a plurality of pixels which are driven by an active matrix method.

Specifically, the display region includes 540 pixels in the row direction and 960 pixels in the column direction, and the pixels are arranged with a pixel pitch of 78 μm in each direction. The resolution of the display region is 326 ppi.

The aperture ratio of the pixels is 44.4%. A transistor including an oxide semiconductor in a channel is included in a pixel circuit. Note that the ratio of the area of the display element 650 to that of the pixel is referred to as the aperture ratio.

The driver circuit SD has a function of supplying an image signal to the pixel circuit, and the driver circuit GD has a function of supplying a selection signal to the pixel circuit. The driver circuit SD and the driver circuit GD include transistors which are fabricated through the same process as the transistor in the pixel circuit.

The insulating layer 690 includes aluminum oxide.

The insulating layer 690 was formed by an atomic layer deposition method. Specifically, trimethylaluminum (TMA; chemical formula: Al(CH₃)₃) and ozone were used as the source material, and a thermal ALD method was employed.

### <<Evaluation>>

The fabricated display module 600 was evaluated. Specifically, the display module 600 was preserved under an environment at a temperature of 85° C. and a humidity of 85%, and then a change in display quality over time was evaluated. Two kinds of display modules 600 having the same structure were evaluated and the results are shown in FIG. 18B. Note that one of the display modules 600 is shown as Sample 1 and the other is shown as Sample 2.

No change from an initial state was found in display quality of the display module 600 which was preserved under an environment at a temperature of 85° C. and a humidity of 85% for 120 hours. Accordingly, it was possible to suppress impurity diffusion to the display element 650 including the organic EL element, which is provided in a region surrounded by the first base 610, the second base 670, and the insulating layer 690. Thus, it was possible to provide the novel, highly reliable display module 600.

### Example 2

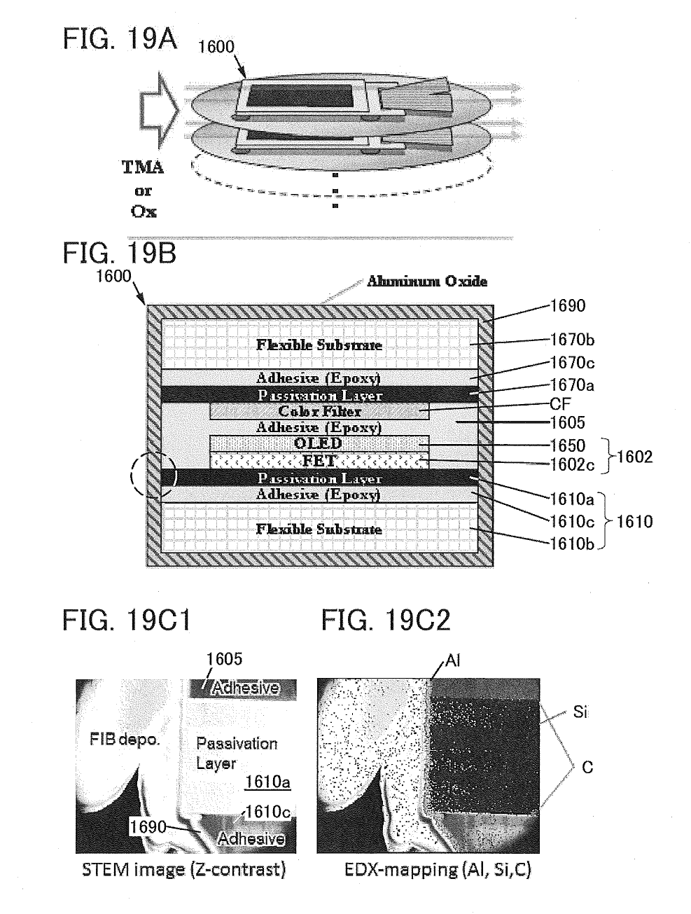

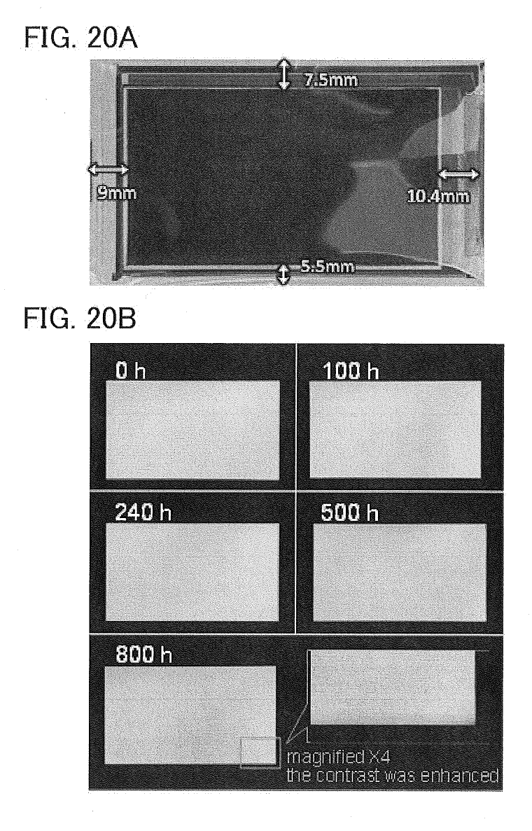

In this example, a fabricated display module of one embodiment of the present invention will be described with reference to FIGS. 19A, 19B, 19C1, and 19C2, FIGS. 20A and 20B, FIGS. 21A to 21C, and FIG. 22.

FIG. 19A is a schematic view illustrating a method of forming an insulating layer 1690 of a fabricated display module 1600, and FIG. 19B is a schematic view illustrating the structure of the fabricated display module 1600. FIG. 19C1 shows a photograph taken with a scanning transmission electron microscope (STEM), which shows the structure of the display module 1600 in a region surrounded by a broken line in FIG. 19B, and FIG. 19C2 shows a photograph taken by energy dispersive X-ray spectrometry (EDX) of the same place.

FIG. 20A shows a photograph of an external view of the fabricated display module 1600. FIG. 20B shows photographs of the display quality of the fabricated display module 1600.

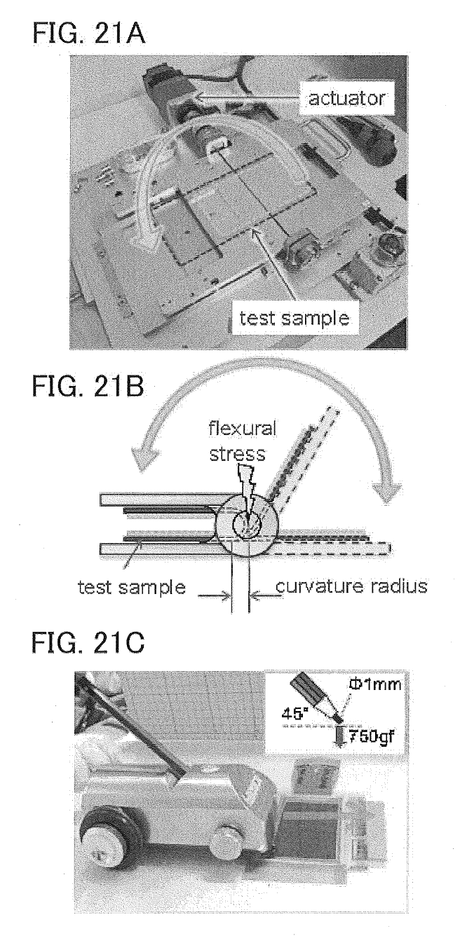

FIG. 21A shows a photograph of an external view of a bend tester, and FIG. 21B is a schematic view illustrating the operation of the bend tester. FIG. 21C shows a photograph of an external view of a pencil hardness tester and a schematic view illustrating the state of a supported pencil.

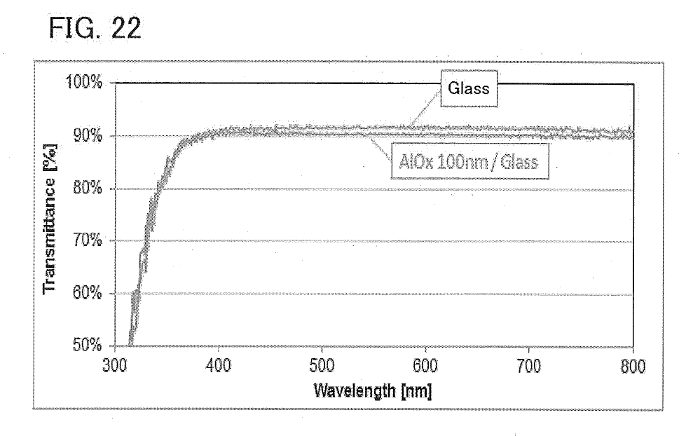

FIG. 22 shows transmittance of a material which can be used for the insulating layer 1690 with respect to visible light.

### <<Structure>>

The fabricated display module 1600 includes a terminal, a first base 1610 which supports the terminal, a second base 1670 which has a region overlapping with the first base 1610, a bonding layer 1605 which has a function of bonding the first base 1610 and the second base 1670, a display element 1650 which is provided between the first base 1610 and the second base 1670 and is electrically connected to the terminal, a flexible printed circuit electrically connected to the terminal, and an insulating layer 1690 in contact with the first base 1610, the second base 1670, the bonding layer 1605, and the flexible printed circuit (see FIG. 19B). Moreover, a coloring layer CF which has a region overlapping with the display element 1650 is included.

Note that a stack including a barrier film 1610a, a flexible base 1610b, and a resin layer 1610c which bonds the barrier film 1610a and the flexible base 1610b can be used for the first base 1610.

A 1.2-μm-thick stacked film including a silicon oxide film, a silicon nitride film, and the like was used as the barrier film 1610a.

An epoxy resin was used for the resin layer 1610c.

For the second base 1670, a structure similar to that of the first base 1610 was used.

An epoxy resin was used for the bonding layer 1605. Note that a distance between the first base 1610 and the second base 1670 is 5 μm. From the observation result of the cross section of the fabricated display module 1600, a side end surface was covered by a film including aluminum (see FIGS. 19C1 and 19C2).

The display module 1600 includes pixels 1602 arranged in a matrix. The pixels 1602 arranged in a matrix include a pixel circuit 1602c and the display element 1650.

A channel-etched transistor was used in the pixel circuit 1602c. In addition, an oxide semiconductor including indium, gallium, and zinc was used for the transistor. Note that a crystalline oxide semiconductor which has c-axis alignment in a direction substantially perpendicular to the surface of the base was used.

Note that the crystalline oxide semiconductor which has c-axis alignment in a direction substantially perpendicular to the surface of the base is referred to as a c-axis-aligned-crystal oxide semiconductor (CAAC-OS). The CAAC-OS has a low density of defect states in the band gap, and the transistor including the CAAC-OS has excellent characteristics and high reliability.

A white-light-emitting tandem organic EL element was used for the display element 1650.

The features of the fabricated display module 1600 are shown in the following table, and its external view is shown in FIG. 20A.

TABLE 1

| | |
|---|---|
| Screen size | 3.4 inch |
| Driving method | Active matrix method |
| The number of | 540 × RGB × 960 |
| effective pixels | |
| Pixel pitch | 0.078 mm × 0.078 mm |
| Resolution | 326 ppi |
| Aperture ratio | 44.4% |
| Source driver | mounted |
| Scan driver | mounted |

### <<Fabrication Method>>

The barrier film 1610a is formed so as to be in contact with a tungsten film formed over one process substrate. Note that a film including tungsten oxide is formed between the barrier film 1610a and the tungsten film.

A wiring and the pixel circuit 1602c are formed over the barrier film 1610a, and the display element 1650 which has a region overlapping with the pixel circuit 1602c is formed by a vapor evaporation method.

A barrier film 1670a is formed so as to be in contact with a tungsten film formed over the other process substrate. In addition, the coloring layer CF is formed over the barrier film 1670a.

The display element 1650 and the coloring layer CF are arranged so as to overlap with each other and are bonded to each other with an epoxy resin.

A separation starting point is formed by irradiating part of the barrier film 1610a with laser light to be separated from the tungsten film. The barrier film 1610a and the tungsten film with the film including tungsten oxide provided between can be separated from each other.

The barrier film 1610a is separated from the process substrate over which the tungsten film is formed and is then bonded to the flexible base 1610b with the resin layer 1610c.

A separation starting point is formed by separating part of the barrier film 1670a from the tungsten film.

The barrier film 1670a is separated from the process substrate over which the tungsten film is formed, and is then bonded to the flexible base 1670b with the resin layer 1670c.

The insulating layer 1690 was formed by a thermal ALD method with TMA and ozone as a source material. Note that FIG. 22 shows transmittance of a material with respect to visible light, with which a 100-nm-thick insulating layer was formed over a glass substrate by the same method as the above thermal ALD method, together with transmittance of a glass substrate. Since the fabricated material has high transmittance with respect to visible light, it can be used favorably for a display screen of the display module.

### <<Evaluation>>

The fabricated display module 1600 was evaluated.

### <<Preservation Test Under High-Temperature and High-Humidity Environment>>

The display module 1600 was preserved under an environment at a temperature of 65° C. and a humidity of 95%, and then a change in display quality over time was evaluated. FIG. 20B shows results of displaying a white image on the entire area before the preservation, and after 100 hours, 240 hours, 500 hours, and 800 hours of the preservation. Note that as for the display module 1600 after 800 hours of the preservation, a photograph of an end portion of the display region which was enlarged to four times its size is shown with emphasis on contrast.

### <<Bending Test>>

After the display module 1600 was repeatedly bent 100,000 times at a frequency of 43 times per minute, the display module 1600 was preserved under an environment at a temperature of 65° C. and a humidity of 95% for 24 hours or longer, and then a change in display quality was evaluated. Note that the evaluation was performed on the display module 1600 which was bent so that the display surface was placed inward and on the display module 1600 which was bent so that the display surface was placed outward. The results are shown in the following table. The external view of the bend tester is shown in FIG. 21A.

TABLE 2

| | when bent so that | when bent so that |
|---|---|---|
| Radius of | display surace | display surface |
| curvature | was placed outward | was placed inward |
| 5 mm | favorable | favorable |
| 4 mm | favorable | favorable |
| 3 mm | favorable | crack caused |

The bend tester had favorable resistance except when the display module 1600 was bent at a radius of curvature of 3 mm so that the display surface was placed inward.

When the display module 1600 was bent at a radius of curvature of 3 mm so that the display surface was placed inward, a crack was caused in the insulating layer 1690. However, there was no influence on the display quality.

### <<Pencil Hardness Test>>

Between lead of a pencil which does not damage the surface of the display module 1600 and lead of a pencil which does not generate a display defect when a load is applied to the display module 1600 using a pencil hardness tester, the hardness of the hardest lead was examined.

FIG. 21C shows the external view of the pencil hardness tester. The pencil hardness tester is provided with a pencil whose lead is sharpened into a column having a flat tip, the pencil is supported at an angle of 45° with respect to the display module, and the lead is pressed with force of 750 gf on the surface of the display module which is placed horizontally.

The pencil hardness tester moved such that the surface of the display module was scanned with the lead of the pencil. Note that a display module in which the insulating layer 1690 was not formed was resistant to a pencil hardness test using a pencil with a hardness of 3H, the surface of the display module was not damaged, and a display defect was not generated.

The display module 1600 in which the insulating layer 1690 was formed was resistant to a pencil hardness test using a pencil with a hardness of 4H, and the effect of the insulating layer 1690 was confirmed.

For example, in this specification and the like, an explicit description “X and Y are connected” means that X and Y are electrically connected, X and Y are functionally connected, and X and Y are directly connected. Accordingly, another element may be provided between elements having a connection relation illustrated in drawings and texts, without being limited to a predetermined connection relation, for example, the connection relation illustrated in the drawings and the texts.

Here, X and Y each denote an object (e.g., a device, an element, a circuit, a wiring, an electrode, a terminal, a conductive film, a layer, or the like).

Examples of the case where X and Y are directly connected include the case where an element that allows an electrical connection between X and Y (e.g., a switch, a transistor, a capacitor, an inductor, a resistor, a diode, a display element, a light-emitting element, and a load) is not connected between X and Y, and the case where X and Y are connected without the element that allows the electrical connection between X and Y provided therebetween.

For example, in the case where X and Y are electrically connected, one or more elements that enable electrical connection between X and Y (e.g., a switch, a transistor, a capacitor, an inductor, a resistor, a diode, a display element, a light-emitting element, or a load) can be connected between X and Y. A switch is controlled to be on or off. That is, a switch is conducting or not conducting (is turned on or off) to determine whether current flows therethrough or not. Alternatively, the switch has a function of selecting and changing a current path. Note that the case where X and Y are electrically connected includes the case where X and Y are directly connected.

For example, in the case where X and Y are functionally connected, one or more circuits that enable functional connection between X and Y (e.g., a logic circuit such as an inverter, a NAND circuit, or a NOR circuit; a signal converter circuit such as a DA converter circuit, an AD converter circuit, or a gamma correction circuit; a potential level converter circuit such as a power supply circuit (e.g., a step-up dc-dc converter, or a step-down dc-dc converter) or a level shifter circuit for changing the potential level of a signal; a voltage source; a current source; a switching circuit; an amplifier circuit such as a circuit that can increase signal amplitude, the amount of current, or the like, an operational amplifier, a differential amplifier circuit, a source follower circuit, or a buffer circuit; a signal generation circuit; a memory circuit; and/or a control circuit) can be connected between X and Y. Note that for example, in the case where a signal output from X is transmitted to Y even when another circuit is interposed between X and Y, X and Y are functionally connected. Note that the case where X and Y are functionally connected includes the case where X and Y are directly connected and the case where X and Y are electrically connected.

Note that in this specification and the like, an explicit description “X and Y are electrically connected” means that X and Y are electrically connected (i.e., the case where X and Y are connected with another element or another circuit provided therebetween), X and Y are functionally connected (i.e., the case where X and Y are functionally connected with another circuit provided therebetween), and X and Y are directly connected (i.e., the case where X and Y are connected without another element or another circuit provided therebetween). That is, in this specification and the like, the explicit description “X and Y are electrically connected” is the same as the description “X and Y are connected”.

Note that, for example, the case where a source (or a first terminal or the like) of a transistor is electrically connected to X through (or not through) Z1 and a drain (or a second terminal or the like) of the transistor is electrically connected to Y through (or not through) Z2, or the case where a source (or a first terminal or the like) of a transistor is directly connected to one part of Z1 and another part of Z1 is directly connected to X while a drain (or a second terminal or the like) of the transistor is directly connected to one part of Z2 and another part of Z2 is directly connected to Y, can be expressed by using any of the following expressions.

The expressions include, for example, “X, Y, a source (or a first terminal or the like) of a transistor, and a drain (or a second terminal or the like) of the transistor are electrically connected to each other, and X, the source (or the first terminal or the like) of the transistor, the drain (or the second terminal or the like) of the transistor, and Y are electrically connected to each other in this order”, “a source (or a first terminal or the like) of a transistor is electrically connected to X, a drain (or a second terminal or the like) of the transistor is electrically connected to Y, and X, the source (or the first terminal or the like) of the transistor, the drain (or the second terminal or the like) of the transistor, and Y are electrically connected to each other in this order”, and “X is electrically connected to Y through a source (or a first terminal or the like) and a drain (or a second terminal or the like) of a transistor, and X, the source (or the first terminal or the like) of the transistor, the drain (or the second terminal or the like) of the transistor, and Y are provided to be connected in this order”. When the connection order in a circuit configuration is defined by an expression similar to the above examples, a source (or a first terminal or the like) and a drain (or a second terminal or the like) of a transistor can be distinguished from each other to specify the technical scope.

Other examples of the expressions include, “a source (or a first terminal or the like) of a transistor is electrically connected to X through at least a first connection path, the first connection path does not include a second connection path, the second connection path is a path between the source (or the first terminal or the like) of the transistor and a drain (or a second terminal or the like) of the transistor, Z1 is on the first connection path, the drain (or the second terminal or the like) of the transistor is electrically connected to Y through at least a third connection path, the third connection path does not include the second connection path, and Z2 is on the third connection path” and “a source (or a first terminal or the like) of a transistor is electrically connected to X at least with a first connection path through Z1, the first connection path does not include a second connection path, the second connection path includes a connection path through which the transistor is provided, a drain (or a second terminal or the like) of the transistor is electrically connected to Y at least with a third connection path through Z2, and the third connection path does not include the second connection path”. Still another example of the expression is “a source (or a first terminal or the like) of a transistor is electrically connected to X through at least Z1 on a first electrical path, the first electrical path does not include a second electrical path, the second electrical path is an electrical path from the source (or the first terminal or the like) of the transistor to a drain (or a second terminal or the like) of the transistor, the drain (or the second terminal or the like) of the transistor is electrically connected to Y through at least Z2 on a third electrical path, the third electrical path does not include a fourth electrical path, and the fourth electrical path is an electrical path from the drain (or the second terminal or the like) of the transistor to the source (or the first terminal or the like) of the transistor”. When the connection path in a circuit configuration is defined by an expression similar to the above examples, a source (or a first terminal or the like) and a drain (or a second terminal or the like) of a transistor can be distinguished from each other to specify the technical scope.

Note that these expressions are examples and there is no limitation on the expressions. Here, X, Y, Z1, and Z2 each denote an object (e.g., a device, an element, a circuit, a wiring, an electrode, a terminal, a conductive film, a layer, or the like).

Even when independent components are electrically connected to each other in a circuit diagram, one component has functions of a plurality of components in some cases. For example, when part of a wiring also functions as an electrode, one conductive film functions as the wiring and the electrode. Thus, “electrical connection” in this specification includes in its category such a case where one conductive film has functions of a plurality of components.

### REFERENCE NUMERALS

BM: light-blocking layer, CF: coloring layer, FPC: flexible printed circuit, FPC1: flexible printed circuit, FPC2: flexible printed circuit, F1: substrate, F2: separation layer, F3: layer to be separated, F3b: conductive layer, F3s: separation starting point, GD: driver circuit, KB: spacer, SD: driver circuit, S1: substrate, S2: separation layer, S3: layer to be separated, S5: base, 30: bonding layer, 31: first adhesive layer, 32: second adhesive layer, 80: process member, 80a: remaining portion, 80b: surface layer, 81: stack, 90: process member, 90a: remaining portion, 90b: surface layer, 91: stack, 91a: remaining portion, 91s: separation starting point, 92: stack, 92c: stack, 92d: stack, 99: nozzle, 10: process member, 180: deposition chamber, 181a: source material supply portion, 181b: source material supply portion, 182: control portion, 182a: flow rate controller, 182b: flow rate controller, 182c: flow rate controller, 182h: heating mechanism, 183: inlet port, 184: outlet port, 185: evacuation unit, 186: support portion, 186P: spacer, 186S: beam portion, 186B: support portion, 187: heating mechanism, 188: door, 300: display module, 300B: display module, 300C: display module: 300D: display module, 300P: display panel, 300PB: display panel, 300PC: display panel, 300PD: display panel, 303G: driver circuit, 301: region, 305: bonding layer, 310: base, 310a: barrier film, 310b: base, 310c: resin layer, 311: wiring, 319: terminal, 350: display element, 370: base, 370a: barrier film, 370b: base, 370c: resin layer, 389: resin layer, 390: insulating layer, 391: opening, 398: resin layer, 450R: display element, 451: electrode, 452: electrode, 453: layer, 470P1: functional film, 470P2: functional film, 500: display module, 501: region, 502: pixel, 502R: subpixel, 505: bonding layer, 510: base, 511: wiring, 519A: terminal portion, 519B: terminal portion, 521: insulating layer, 528: partition wall, 550R: display element, 551R: electrode, 552: electrode, 553: layer containing a light-emitting organic compound, 570: base, 570P: functional film, 571: insulating layer, 576: opening, 590: insulating layer, 591: opening, 600: display module, 605: bonding layer, 610: base, 619: terminal, 650: display element, 670: base, 690: insulating layer, 1600: display module, 1602: pixel, 1602c: pixel circuit, 1605: bonding layer, 1610: base, 1610a: barrier film, 1610b: base, 1610c: resin layer, 1650: display element, 1670: base, 1670a: barrier film, 1670b: base, 1670c: resin layer, 1690: insulating layer, 3000A: data processor, 3000B: data processor, 3000C: data processor, 3101: housing, 3101b: housing, 3120: input/output portion, 3120b: input/output portion, 4000A: data processor, 4000B: data processor, 4000C: data processor, 4101: housing, 4101b: housing, 4120: input/output portion, 4120b: input/output portion

This application is based on Japanese Patent Application serial no. 2014-241556 filed with Japan Patent Office on Nov. 28, 2014, Japanese Patent Application serial no. 2014-242992 filed with Japan Patent Office on Dec. 1, 2014, Japanese Patent Application serial no. 2015-045490 filed with Japan Patent Office on Mar. 9, 2015, and Japanese Patent Application serial no. 2015-129863 filed with Japan Patent Office on Jun. 29, 2015, the entire contents of which are hereby incorporated by reference.

1. A display module comprising:
a terminal;
a first base;
a second base including a first region overlapping with the first base;
a bonding layer;
a display element between the first base and the second base, the display element being electrically connected to the terminal;
a flexible printed circuit electrically connected to the terminal; and
an insulating layer in contact with the first base, the second base, the bonding layer, and the flexible printed circuit,
wherein the first base is flexible,
wherein the first base is configured to support the terminal,
wherein the second base is flexible, and
wherein the bonding layer is configured to bond the first base and the second base.

2. The display module according to claim 1 further comprising a resin layer, wherein the insulating layer includes a second region interposed between the bonding layer and the resin layer.

3. The display module according to claim 1, wherein the display element includes a layer containing a light-emitting organic compound.

4. The display module according to claim 1 further comprising a driver circuit, wherein a distance between the driver circuit and an end portion of the first base or an end portion of the second base which is the closest to the driver circuit is longer than 0 mm and shorter than or equal to 1.0 mm.

5. The display module according to claim 1 further comprising a driver circuit,
wherein the driver circuit is provided between the display element and an end portion of the first base, and
wherein a distance between the display element and the end portion of the first base or an end portion of the second base which is the closest to the display element is longer than 0 mm and shorter than or equal to 4.0 mm.

6. The display module according to claim 1, wherein a distance between the display element and an end portion of the first base or an end portion of the second base which is the closest to the display element is longer than 0 mm and shorter than or equal to 3.0 mm.

7. A display module comprising:
a first terminal portion;
a second terminal portion;
a first base;
a second base;
a bonding layer;
a display element between the first base and the second base, the display element being electrically connected to the first terminal portion;
a touch sensor between the first base and the second base, the touch sensor being electrically connected to the second terminal portion;
a first flexible printed circuit electrically connected to the first terminal portion;
a second flexible printed circuit electrically connected to the second terminal portion; and
an insulating layer in contact with the first base, the second base, the bonding layer, the first flexible printed circuit, and the second flexible printed circuit,
wherein the first base is flexible,
wherein the first base is configured to support the first terminal portion,
wherein the second base is flexible,
wherein the second base is configured to support a first region overlapping with the first base and the second terminal portion,
wherein the bonding layer is configured to bond the first base and the second base, and
wherein the display element includes a layer containing a light-emitting organic compound.

8. A method for manufacturing the display module according to claim 1, comprising the steps of:
a first step of preparing a process member including the terminal, the first base which supports the terminal, the second base which has the first region overlapping with the first base, the bonding layer which bonds the first base and the second base, the display element which is provided between the first base and the second base and is electrically connected to the terminal, and the flexible printed circuit electrically connected to the terminal, and forming a mask in a third region overlapping with a terminal portion of the flexible printed circuit;
a second step of forming the insulating layer in contact with the first base, the second base, the bonding layer, and the flexible printed circuit by an atomic layer deposition method; and
a third step of removing a part of the insulating layer together with the mask, and forming an opening in a fourth region of the insulating layer wherein the fourth region overlaps with the terminal portion of the flexible printed circuit.
